(19) United States
(12) Patent Application Publication
(10) Pub. No.: US 2026/0096144 A1
(43) Pub. Date: Apr. 2, 2026

(54) BACKSIDE TRANSISTORS IN SEMICONDUCTOR DEVICES

(71) Applicant: Taiwan Semiconductor Manufacturing Company, Ltd., Hsinchu (TW)

(72) Inventors: Hung-Yu YEN, Taipei (TW); Keng-Chu LIN, Pintung (TW); Yu-Yun PENG, Hsinchu (TW)

(73) Assignee: Taiwan Semiconductor Manufacturing Company, Ltd., Hsinchu (TW)

(21) Appl. No.: 18/899,467

(22) Filed: Sep. 27, 2024

(51) Int. Cl. H01L 29/423; H01L 21/8234; H01L 27/088; H01L 29/06; H01L 29/08; H01L 29/417; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/251; H10D 84/0128; H10D 84/038; H10D 84/83

(57) ABSTRACT

The present disclosure discloses a semiconductor device including a front side device and a backside device with a common gate structure. The semiconductor device includes a base structure having a first doped region, a plurality of nanostructured channel layers disposed on the first doped region, a second doped region disposed in the first doped region, a vertical channel region disposed in the plurality of nanostructured channel layers and in contact with the second doped region, and a gate structure surrounding the plurality of nanostructured channel layers and second vertical channel region.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around FETs (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIGS. 1B-1E illustrate cross-sectional views of a semiconductor device with nanostructured vertical and horizontal channel layers and a backside device, in accordance with some embodiments.

FIG. 2 is a flow diagram of a method for fabricating a semiconductor device with nanostructured vertical and horizontal channel layers and a backside device, in accordance with some embodiments.

FIGS. 3A-23A, 3B-23B, 7C, 9C, and 15C-23C illustrate different cross-sectional views of a semiconductor device with nanostructured vertical and horizontal channel layers and a backside device at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The present disclosure provides a backside device (e.g., a backside FET) formed within a substrate and on a backside of the substrate and powered through the backside of the substrate. The backside device can be fabricated as a FET which can be a backside pFET or a backside nFET. The front side of the substrate can have front side devices (e.g., n-type FETs, p-type FETs, gate-all-around p-type GAA FETS and n-type GAA FETs). To form the backside device, doped regions can be formed within the substrate. These doped regions can function as source/drain regions of the backside device. The source/drain regions can be powered or controlled through electrical contacts of a backside power delivery structure on the backside of the substrate. In some embodiments, a common gate can control the front side device and the backside device. For example, a GAA FET can be formed on the front side of the substrate. Doped regions which can function as source/drain regions for a backside device can be formed within the substrate. The source/drain regions for the backside device can be controlled through contact structures on the backside of the substrate. The front side GAA FET can include a nanostructured vertical channel (NVC) region disposed within a plurality of nanostructured horizontal channel (NHC) layers disposed on a base structure. The NVC regions can be connected to the source and drain of the backside device. The gate structure of the front side GAA FET can wrap around the NVC regions. Vertical portions of two adjacent NVC regions can be connected by a NHC layer of the plurality of NHC layers to form a channel for the backside device, which can be controlled by the gate structure.

The present disclosure further provides integration of the front side device with the backside device to improve computing performance. An increased amount of power required for powering the backside device is provided by a backside power delivery structure. The present disclosure further provides methods of forming the backside devices with source/drain regions embedded within the substrate to promote better utilization of the substrate, which in turn increases chip density and device scaling. The present disclosure also provides additional routing through the backside power delivery structure for signal control of the backside device, thereby boosting device performance.

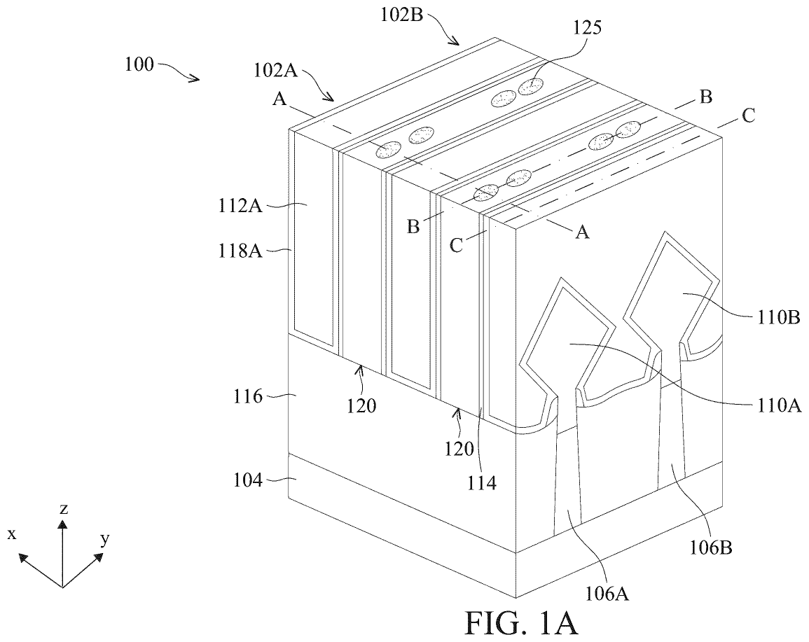

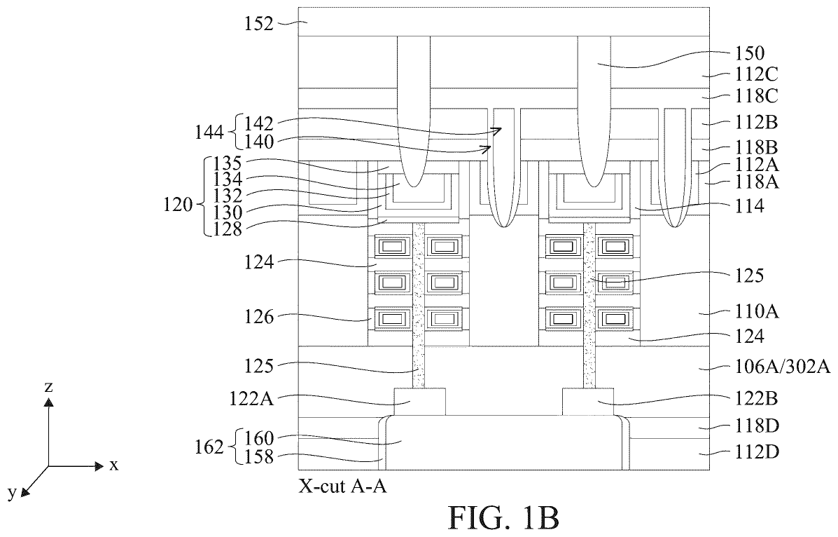

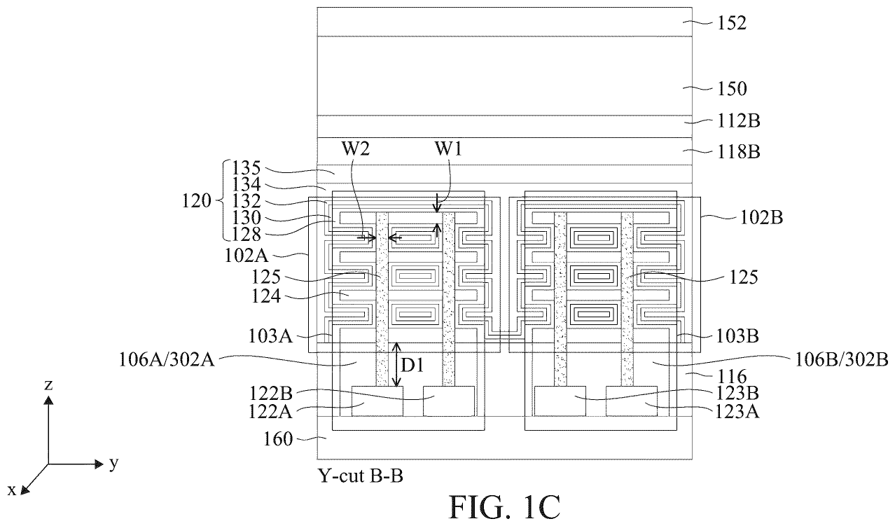

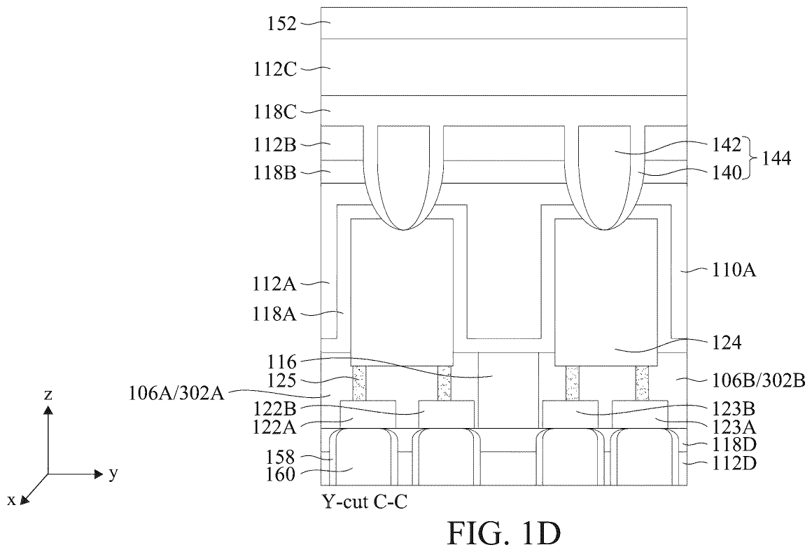

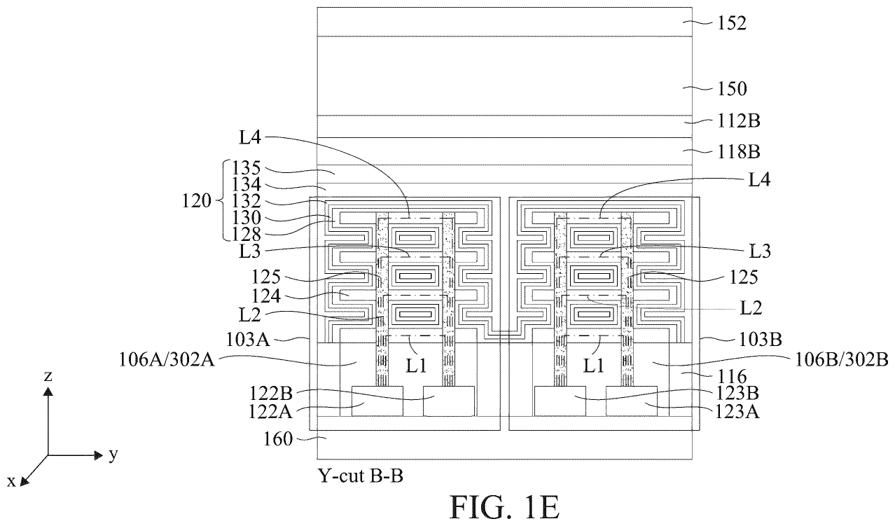

A semiconductor device 100 with FETs 102A and 102B is described with reference to FIGS. 1A-1E, according to various embodiments. In some embodiments, FETs 102A and 102B can represent GAA FETs. Though two FETs are discussed with reference to FIGS. 1A-1E, semiconductor device 100 can have any number of FETs. FETs 102A and 102B can be n-type, p-type, or a combination thereof. FIG. 1A illustrates an isometric view of semiconductor device 100, according to some embodiments. Semiconductor device 100 can have different cross-sectional views along lines A-A, B-B, and C-C of FIG. 1A, according to various embodiments. Line A-A can extend along the x-axis and lines B-B and C-C can extend along the y-axis.

According to various embodiments, (i) FIG. 1B illustrates a cross sectional view of FET 102A along line A-A of FIG. 1A, (ii) FIGS. 1C and 1E illustrate cross-sectional views of FETs 102A and 102B along line B-B of FIG. 1A, and (iii) FIG. 1D illustrates a cross-sectional view of FETs 102A and FET 102B along line C-C of FIG. 1A. FIGS. 1B-1E illustrate cross-sectional views of FETs 102A and 102B with additional elements that are not shown in FIG. 1A for simplicity. The discussion of FET 102A applies to FET 102B, unless mentioned otherwise. The discussion of elements in FIGS. 1A-1E with the same annotations applies to each other, unless mentioned otherwise.

Referring to FIGS. 1A-1E, semiconductor device 100 can be formed on a substrate 104. Substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic).

Semiconductor device 100 can further include base structures 106A and 106B (also referred to as “sheet bases,” “fin bases,” or protrusion) which can extend along an x-axis. Base structures 106A and 106B can be separated by shallow trench isolation (STI) regions 116. Base structure 106A can be doped with p-type dopants to form p-well 302A and base structure 106B can be doped with n-type dopants to form n-well 302B. Base structure 106A can include n-type doped regions 122A and 122B. Similarly, base structure 106B can include p-type doped regions 123A and 123B. N-type doped regions 122A and 122B and p-type doped regions 123A and 123B can also be referred to as “doped regions.” Although FIGS. 1C-1E show two doped regions for each of FETs 102A and 102B, in some embodiments there can be more than two doped regions for each of FETs 102A and 102B.

Referring to FIGS. 1B-1E, in some embodiments, FET 102A can further include (i) a stack of nanostructured horizontal channel (NHC) layers 124 (also referred to as “nanostructured layers 124” or “nanostructured channel regions 124”) disposed on base structure 106A, (ii) nanostructured vertical channel (NVC) regions 125 extending through the stack of NHC layers 124 and disposed on n-type doped regions 122A and 122B, (iii) GAA structure 120 (also referred to as “gate structure 120”) disposed on and around NHC layers 124, (iv) epitaxial source/drain (S/D) regions 110A disposed on portions of base structure 106A adjacent to NHC layer 124, (v) S/D contact structures 144 disposed on epitaxial S/D regions 110A, and (vi) gate contact structure 150 disposed on gate structure 120. Similarly, referring to FIGS. 1C-1E, in some embodiments, FET 102B can further include (i) a stack of NHC layers 124 disposed on base structure 106B, (ii) NVC regions 125 extending through the stack of NHC layers 124 and disposed on p-type doped regions 123A and 123B, (iii) GAA structure 120 disposed on and around NHC layers 124, (iv) epitaxial S/D regions 110B disposed on portions of base structure 106B adjacent to NHC layer 124, (v) S/D contact structures 144 disposed on epitaxial S/D regions 110B, and (vi) gate contact structure 150 disposed on gate structure 120. The term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, NHC layers 124 can be in the form of nanosheets, nanowires, nanorods, nanotubes, or other suitable nanostructured shapes.

As shown in FIGS. 1B, 1C and 1E, NHC layers 124 surrounds each of NVC region 125. In some embodiments, each of NHC layers 124 can include Si, silicon arsenic (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. Though rectangular cross-sections of NHC layers 124 are shown, NHC layers 124 can have cross-sections of other geometric shapes (e.g., circular, elliptical, triangular, or polygonal).

As shown in FIGS. 1B and 1C, for FET 102A, NVC region 125 can extend along a z-axis from an uppermost NHC layer of the stack of NHC layers 124 to n-type doped regions 122A and 122B. Similarly, for FET 102B, NVC regions 125 can extend from an uppermost NHC layer of the stack of NHC layers 124 to p-type doped regions 123A and 123B. A first portion of NVC region 125 is wrapped around or surrounded by the portion of gate structure 120 that surrounds NHC layers 124. Therefore, gate structure 120 can be in physical contact with NVC region 125. Gate structure 120 can be used to control conduction of holes or electrons through NVC region 125. A second portion of NVC region 125 of FET 102A can be surrounded by the p-well 302A of base structure 106A. Similarly, a second portion of NVC region 125 of FET 102B can be surrounded by n-well 302B of base structure 106B. In some embodiments, each of NVC regions 125 can include Si, SiAs, SiP, SiC, SiCP, SiGe, SiGeB, GeB, SiGeSnB, a III-V semiconductor compound, or other suitable semiconductor materials. In some embodiments, NVC region 125 and NHC layers 124 can have the same material or materials different from each other. In some embodiments, NVC region 125 can be undoped or can be doped with p-type dopants (e.g., boron, indium, aluminum, or gallium) or n-type dopants (e.g., phosphorus or arsenic).

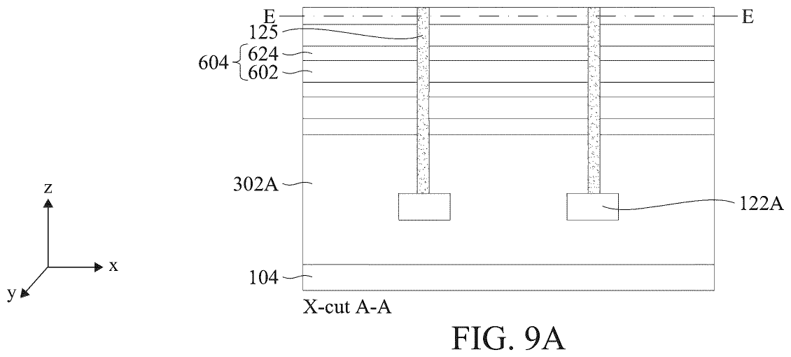

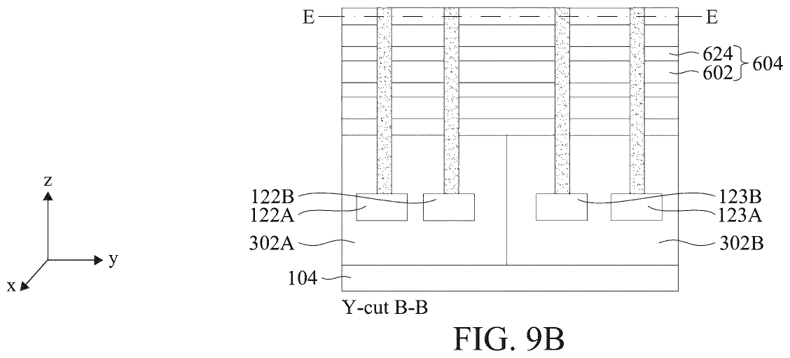

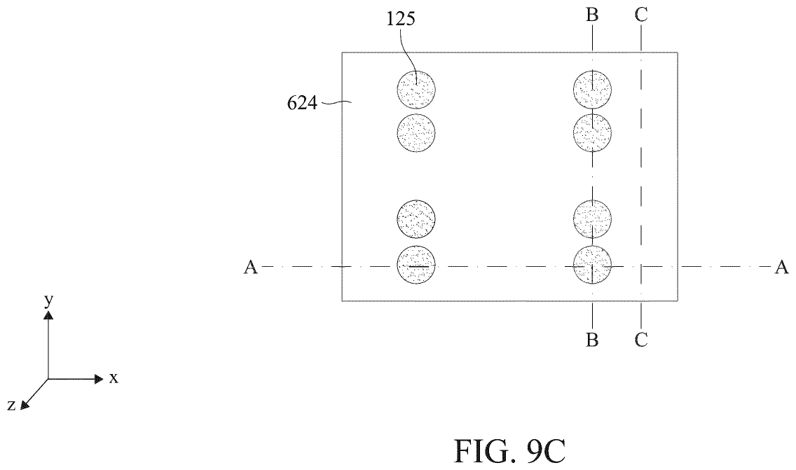

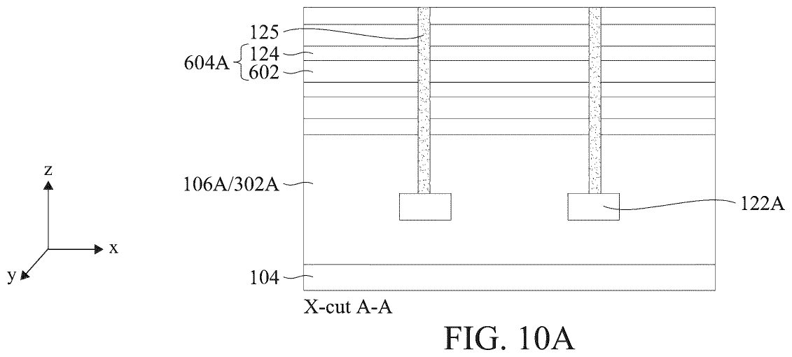

NVC region 125 can have a circular cross-section along an X-Y plane as shown in FIG. 1A, and in FIG. 9C, which is a top-down view of FET 102A through the uppermost NHC layer 124. In some embodiments, NVC region 125 can have a cross-section of other geometric shapes (e.g., rectangular, elliptical, or polygonal; not shown) along an X-Y plane. In some embodiments, NVC region 125 can have a width W1 along an X-axis and/or Y-axis (or a diameter W1) ranging from about 1 nm to about 10 nm. In some embodiments, a ratio of the width W1 to width W2 of NHC layer 124 can be between about 1 and about 20. In some embodiments, as shown in FIG. 1C, a depth D1 of the portion of NVC region 125 below a lowermost NHC layer 124 of the stack of NHC layers 124 can be between about 1 nm and about 20 nm. As NVC regions 125 are not visible in cross-sectional view along line C-C, the relative positions of NVC regions 125 are illustrated in FIG. 1D with dashed lines.

Referring to FIGS. 1B and 1D, epitaxial S/D regions 110A and 110B can be grown on base structure 106A and 106B and can include epitaxially-grown semiconductor materials. In some embodiments, the epitaxially-grown semiconductor material can include the same material or a different material from the material of substrate 104. Epitaxial S/D regions 110A and 110B can be n- or p-type. The term “p-type” defines a structure, layer, and/or region as being doped with p-type dopants, such as boron. The term “n-type” defines a structure, layer, and/or region as being doped with n-type dopants, such as phosphorus. In some embodiments, epitaxial S/D regions 110A and 110B can include SiAs, SiC, SiCP, SiGe, SiGeB, GeB, SiGeSnB, a III-V semiconductor compound, any other suitable semiconductor material, or a combination thereof.

In some embodiments, each of S/D contact structures 144 on epitaxial S/D regions 110A and 110B can include (i) a silicide layer (not shown), (ii) a S/D metal contact layer 142 disposed on silicide layer, and (iii) a liner 140. In some embodiments, silicide layer can include nickel silicide (NiSi), tungsten silicide (WSi₂), titanium silicide (TiSi₂), cobalt silicide (CoSi₂), or other suitable metal silicides. In some embodiments, S/D metal contact layer 142 can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), any other suitable conductive material, and a combination thereof. In some embodiments, liner 140 can include a nitride material, such as titanium nitride (TiN) and tantalum nitride (TaN).

Gate structure 120 can be a multi-layered structure and can surround NHC layers 124, as shown in FIGS. 1B, 1C and 1E. Gate structure 120 also surrounds NVC region 125, as shown in FIGS. 1B, 1C, and 1E. Gate structure 120 can be referred to as “gate-all-around (GAA) structure.” A first portion of the gate structure 120 disposed on the stack of NHC layers 124 can be electrically isolated from adjacent S/D regions 110A and 110B by outer gate spacers 114. A second portion of the gate structure 120 surrounding NHC layers 124 can be electrically isolated from adjacent S/D regions 110A and 110B by inner gate spacers 126. Inner gate spacers 126 and outer gate spacers 114 can include an insulating material, such as SiO₂, SiN, SiCN, SiOCN, and any other suitable insulating material.

Gate structure 120 can include (i) an interfacial oxide layer (IL) 128, (ii) a high-k (HK) gate dielectric layer 130, (iii) a work function metal (WFM) layer 132, (iv) a gate metal fill layer 134, and (v) a gate capping layer 135. FIGS. 1B, 1C, and 1E show that all the layers of GAA structure 120 are wrapped around NHC layers 124 and NVC region 125.

IL layers 128 can be disposed on NHC layers 124 and NVC region 125. In some embodiments, IL layers 128 can include SiO₂, silicon germanium oxide (SiGeOₓ), germanium oxide (GeOₓ), or other suitable oxide materials. HK gate dielectric layers 130 can be disposed on IL layers 128 and can include (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. The term “high-k” refers to a high dielectric constant. In the field of semiconductor device structures and manufacturing processes, high-k refers to a dielectric constant that is greater than the dielectric constant of SiO₂ (e.g., greater than 3.9).

WFM layer 132 can be n- or p-type for n or p-type FET 102A, respectively. In some embodiments, n-type WFM layer 132 can include a metallic material with a work function value closer to a conduction band energy than a valence band energy of a material of NHC layers 124. For example, n-type WFM layer 132 can include an Al-based or Al-doped metallic material with a work function value less than 4.5 eV (e.g., about 3.5 eV to about 4.4 eV), which can be closer to the conduction band energy (e.g., 4.1 eV of Si or 3.8 eV of SiGe) than the valence band energy (e.g., 5.2 eV of Si or 4.8 eV of SiGe) of Si-based or SiGe-based NHC layers 124. In some embodiments, n-type WFM layer 132 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, other suitable Al-based materials, or a combination thereof.

In some embodiments, p-type WFM layer 132 can include a metallic material with a work function value closer to a valence band-edge energy than a conduction band-edge energy of a material of NHC layer 124. For example, p-type WFM layer 132 can include a substantially Al-free (e.g., with no Al) metallic material with a work function value equal to or greater than 4.5 eV (e.g., about 4.5 eV to about 5.5 eV), which can be closer to the valence band-edge energy (e.g., 5.2 eV of Si or 4.8 eV of SiGe) than the conduction band-edge energy (e.g., 4.1 eV of Si or 3.8 eV of SiGe) of Si-based or SiGe-based NHC layers 124. In some embodiments, p-type WFM layer 132 can include substantially Al-free (e.g., with no Al): (i) Ti-based nitrides or alloys, such as TiN, TiSiN, titanium gold (Ti—Au) alloy, titanium copper (Ti—Cu) alloy, titanium chromium (Ti—Cr) alloy, titanium cobalt (Ti—Co) alloy, titanium molybdenum (Ti—Mo) alloy, and titanium nickel (Ti—Ni) alloy; (ii) Ta-based nitrides or alloys, such as TaN, TaSiN, Ta—Au alloy, Ta—Cu alloy, Ta—W alloy, tantalum platinum (Ta—Pt) alloy, Ta—Mo alloy, Ta—Ti alloy, and Ta—Ni alloy; (iv) metal nitrides, such as molybdenum nitride (MoN) and tungsten nitride (WN); (iii) other suitable Al-free metallic materials; (iv) and combinations thereof. In some embodiments, WFM layer 132 can include a thickness ranging from about 1 nm to about 4 nm.

In some embodiments, gate metal fill layer 134 can include a suitable conductive material, such as tungsten (W), titanium (Ti), silver (Ag), ruthenium (Ru), molybdenum (Mo), copper (Cu), cobalt (Co), aluminum (Al), iridium (Ir), nickel (Ni), any other suitable conductive material, and a combination thereof. In some embodiments, gate metal fill layer 134 can include a substantially fluorine-free metal layer (e.g., fluorine-free W). The substantially fluorine-free metal layer can include an amount of fluorine contaminants less than about 5 atomic percent in the form of ions, atoms, and/or molecules. In some embodiments, gate contact structures 150 on gate structures 120 can include conductive materials similar to S/D contact metal layer 142.

Referring to FIGS. 1B-1E, in some embodiments, FET 102A can further include first, second and third etch stop layers (ESL) 118A-118C, first, second, and third interlayer dielectric (ILD) layers 112A-112C, and STI regions 116. First, second, and third ESL 118A-118C can be configured to protect gate structures 120 and/or epitaxial (S/D) regions 110A and 110B. First, second and third ILD layers 112A-112C can be disposed on first, second and third ESL 118A-118C respectively. First ILD layer 112A can be interposed between first ESL layer 118A and second ESL 118B. Similarly, second ILD layer 112B can be interposed between second and third ESL layer 118B and 118C. Third ILD layer 112C can be formed on third ESL layer 118C. In some embodiments, STI regions 116, first, second and third ESL 118A-118C, and first, second, and third ILD layer 112A-112C can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ), and any other suitable insulating material.

In some embodiments, S/D contact structure 144 can extend from epitaxial S/D region 110A or 110B to bottom surface of third ESL 118C. First ILD layer 112A, first ESL 118A, second ILD layer 112B and second ESL 118B can surround S/D contact structure 144. In some embodiments, gate contacts structure 150 can extend from gate metal fill layer 134 to front side interconnect structure 152. Gate contact structure 150 can be surrounded by gate structure 120, second ESL 118B, second ILD layer 112B, third ESL 118C, and third ILD layer 112C. In some embodiments front side interconnect structure 152 can be formed on third ILD layer 112C and can be configured to electrically connect FETs 102A and 102B to overlying power supplies and/or other devices (not shown).

Referring to FIGS. 1B-1E, in some embodiments, semiconductor device 100 can further include a first backside contact structure 162 for powering and/or controlling n-type doped regions 122A and 122B and a second backside contact structure 162 for powering and/or controlling p-type doped regions 123A and 123B. In some embodiments, backside contact structures 162 can include (i) a backside silicide layer (not shown), (ii) a backside contact metal layer 160 disposed on the backside silicide layer, and (iii) a backside liner 158 disposed on backside contact metal layer 160. The discussion of silicide layers, S/D contact metal layer 142, liners 140 of S/D contact structures 144 applies to backside silicide layer, backside contact metal layer 160, and backside liner 158, respectively, unless mentioned otherwise. Backside contact metal layer 160 can also be referred to as backside contact metal structure. In some embodiments backside contact structures 162 can be surrounded by backside ESL 118D and backside ILD layer 112D. In some embodiments, backside ESL layer 118D can contact a backside of STI region 116, a backside of base structure 106A and a backside of base structure 106B.

Referring to FIG. 1C, in some embodiments, semiconductor device 100 can include (i) front side FET 102A on the front side of the substrate, having NHC layers 124, gate structure 120, source drain regions 110A, S/D contact structure 144, and gate contact structure 150 and (ii) a backside device 103A having n-type doped regions 122A and 122B, NVC region 125, gate structure 120, and backside contact structure 162. Semiconductor device 100 can further include FET 102B having (i) front side FET 102B on the front side of the substrate having NHC layers 124, gate structure 120, source drain regions 110B, and front side interconnect structure 152, and (ii) a backside device 103B having p-type doped regions 123A and 123B, NVC region 125, gate structure 120, and backside contact structure 162. The backside devices 103A and 103B can represent a backside nFET 103A and a backside pFET 103B. Even though FIGS. 1A-1E show two front side FETs 102A and 102B and two backside FETs 103A and 103B, the present disclosure is not limited to the number of FETs shown. An example method for fabricating semiconductor device 100 as described in the present disclosure can be used to form any number of front side and backside FETs.

Referring to FIG. 1E, in some embodiments, backside device 103A can function as a backside n-FET wherein n-type doped regions 122A and 122B can form source and drain regions, and a portion of NVC region 125 and NHC layer 124 can form a backside device channel region. Gate structure 120 surrounding the portion of NVC region 125 and NHC layer 124 forming the backside device channel region can control the backside device channel region. Similarly, in some embodiments, backside device 103B can function as a backside p-FET wherein p-type doped regions 123A and 123B can form source and drain regions, and a portion of NVC region 125 and NHC layer 124 can form a backside device channel region. Gate structure 120 surrounding the portion of NVC region 125 and NHC layer 124 forming the backside device channel region can control the backside device channel region. Each NHC layer 124 of the stack of NHC layers in combination with NVC regions 125 leading from n-type doped regions 122A and 122B or from p-type doped regions 123A and 123B to NHC layer 124 can form backside device channel regions of different lengths. For example, FIG. 1E shows backside device channel regions of lengths L1, L2, L3, and L4. Backside devices 103A and 103B can have as many backside channel regions as a number of NHC layers 124 in the stack of NHC layers.

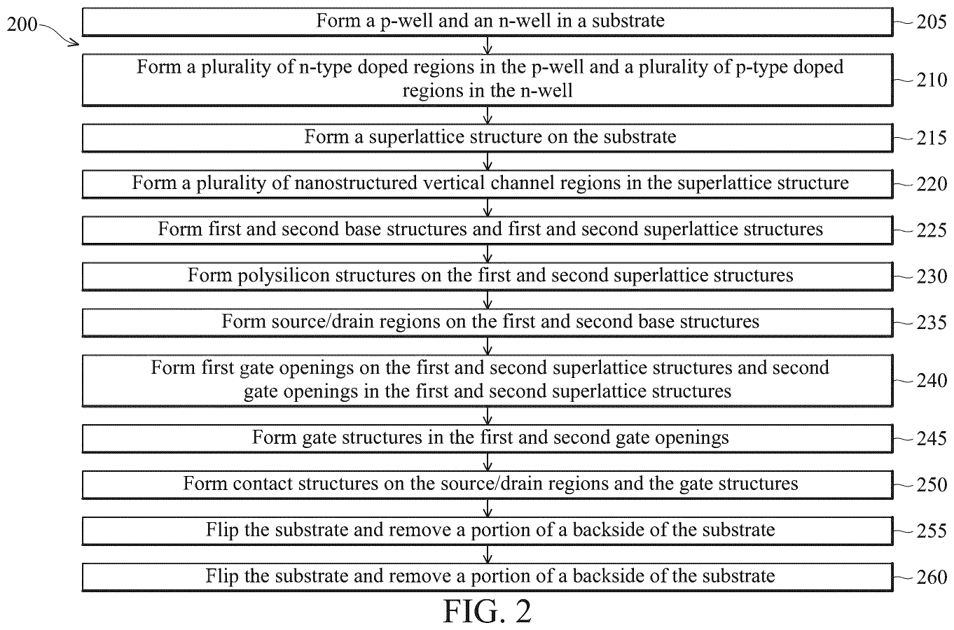

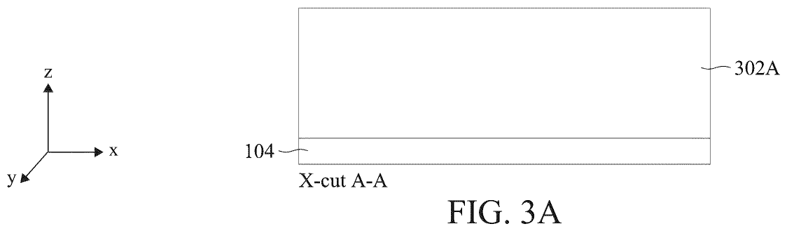

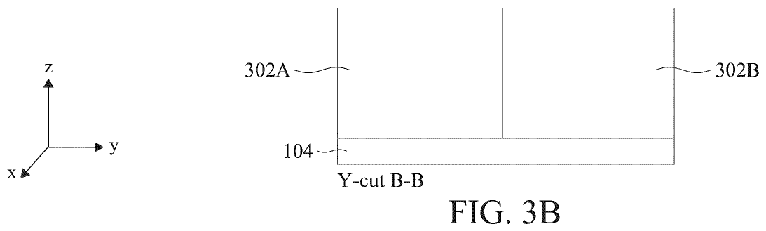

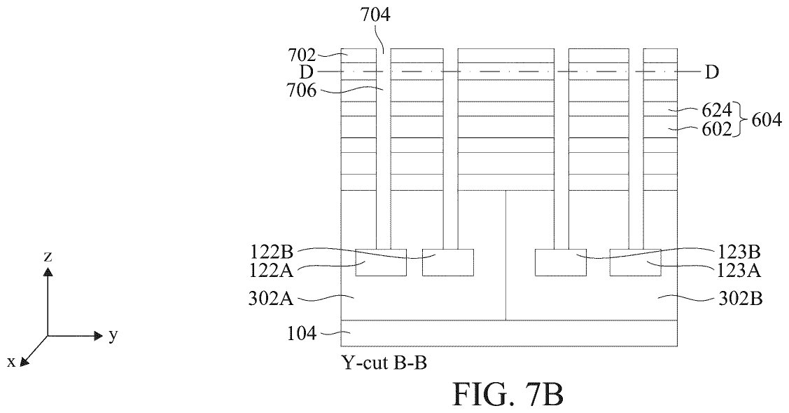

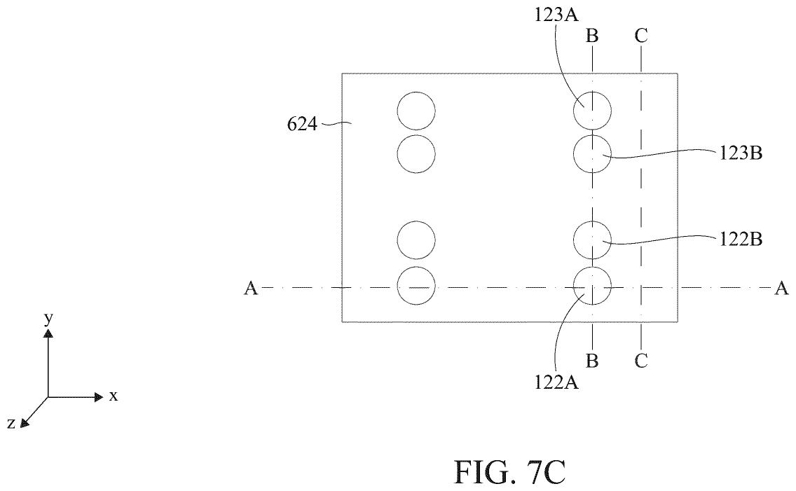

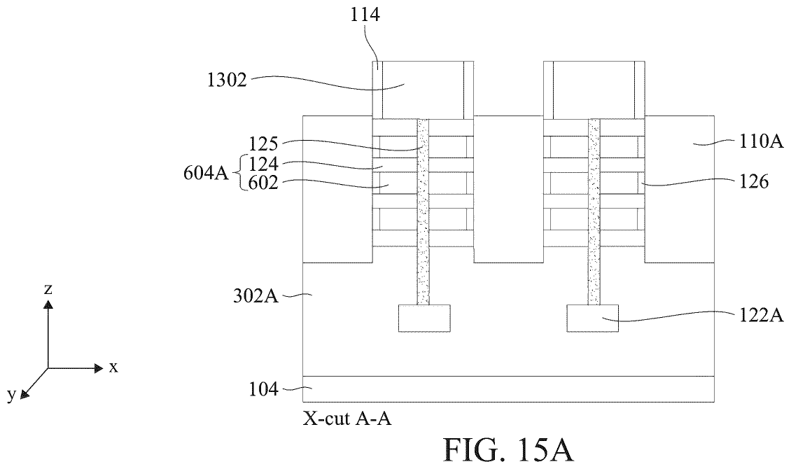

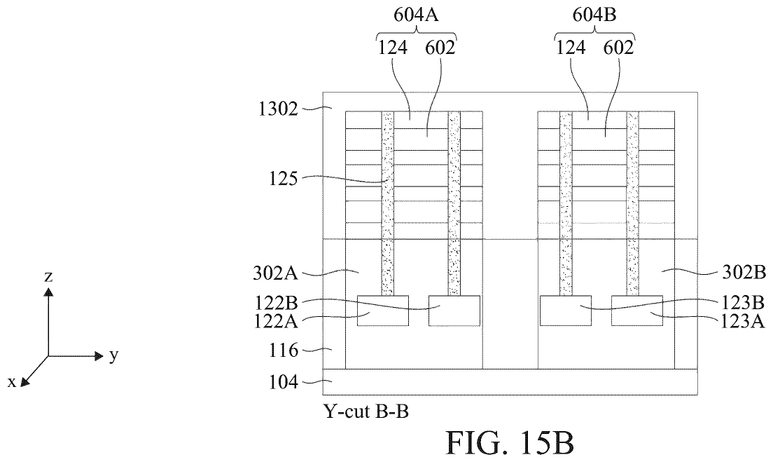

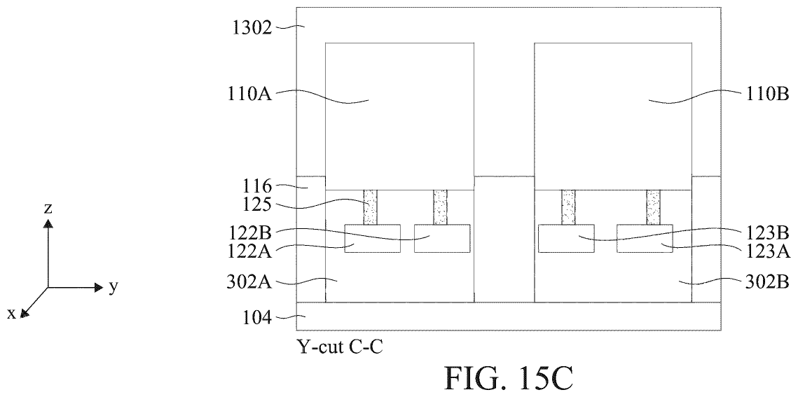

FIG. 2 is a flow diagram of an example method 200 for fabricating semiconductor device 100 as shown in FIGS. 1A-1E, according to some embodiments. For illustrative purposes, the operations illustrated in FIG. 2 will be described with reference to the example fabrication process for fabricating semiconductor device 100 as illustrated in FIGS. 3A-23A, 3B-23B, 7C, 9C, and 15C-23C. FIGS. 3A-23A are cross-sectional views of semiconductor device 100 along line A-A FIG. 1A at various stages of fabrication, according to some embodiments. FIGS. 3B-23B are cross-sectional views of semiconductor device 100 along line B-B of FIG. 1A at various stages of fabrication, according to some embodiments. FIGS. 15C-23C are cross-sectional views of semiconductor device 100 along line C-C of FIG. 1A at various stages of fabrication, according to some embodiments. FIG. 7C is a top down view of semiconductor device 100 along lines D-D of FIGS. 7A and 7B at a stage of fabrication, according to some embodiments. FIG. 9C is a top down view of semiconductor device 100 along lines E-E of FIGS. 9A and 9B at a stage of fabrication, according to some embodiments. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. Elements in FIGS. 3A-23A, 3B-23B, 7C, 9C, and 15C-23C with the same annotations as elements in FIGS. 1A-1E are described above.

Referring to operation 205, a p-well and an n-well is formed in a substrate. For example, as shown in FIGS. 3A and 3B, a portion of substrate 104 can be p-type doped to form p-well 302A and another portion of substrate 104 can be n-type doped to form n-well 302B. For forming p-well 302A, a hard mask layer can be patterned using photolithography to create an opening in the hard mask layer. The portion of the substrate uncovered by the hard mask layer can be doped with p-type dopants using a diffusion process or an ion implantation process. P-well 302A can have a p-type dopant concentration of about 1×10¹⁷ atoms/cm³ to about 1×10²² atoms/cm³. For forming n-well 302B, the hard mask layer can be patterned using photolithography to cover p-well 302A. The portion of the substrate uncovered by the hard mask layer can be doped with n-type dopants using a diffusion process or an ion implantation process. N-well 302B can have a n-type dopant concentration of about 1×10¹⁷ atoms/cm³ to about 1×10²² atoms/cm³.

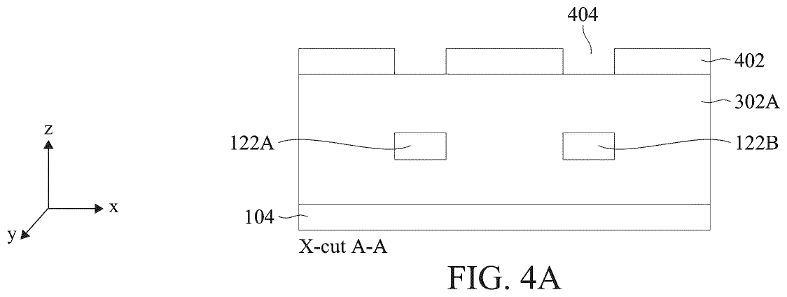

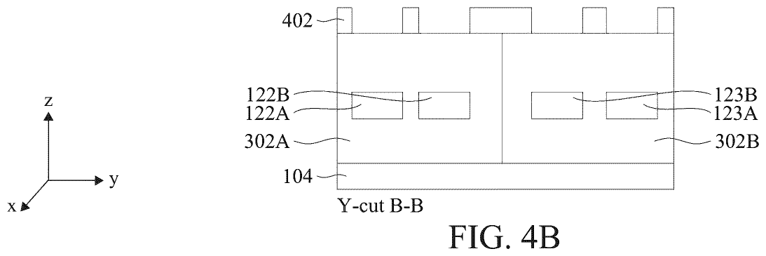

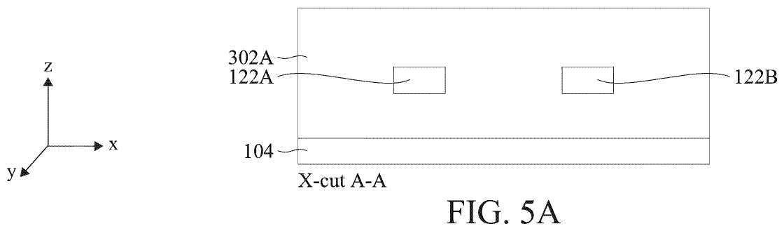

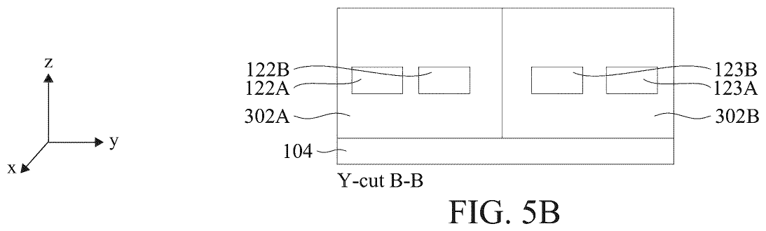

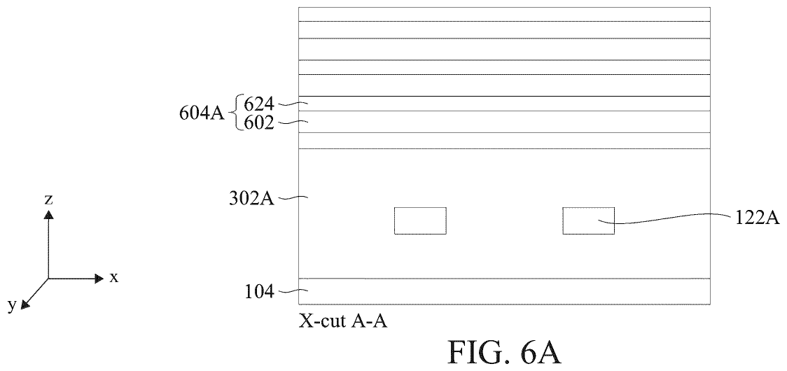

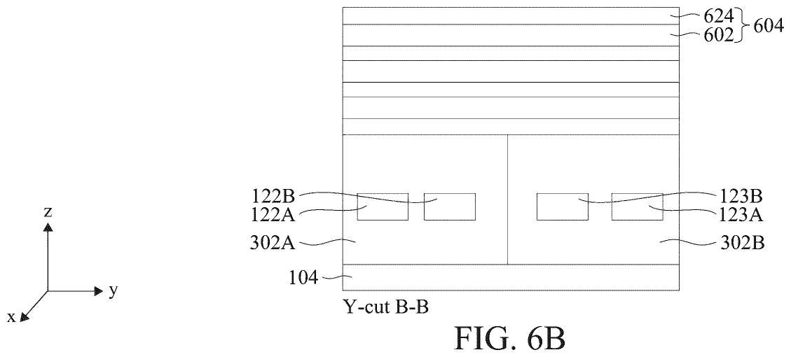

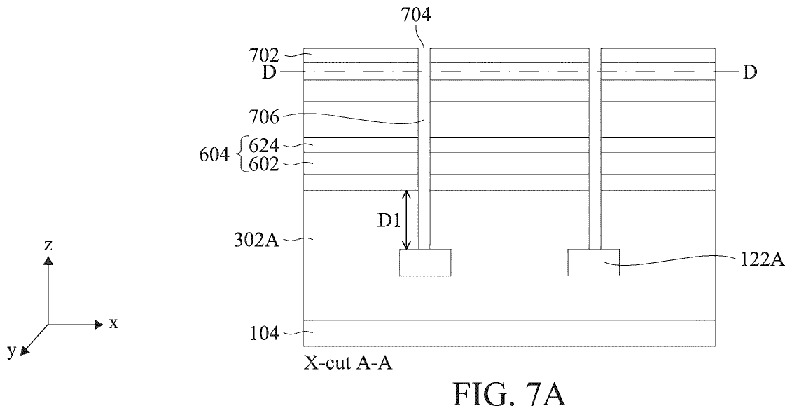

Referring to operation 210, a plurality of n-type doped regions are formed in the p-well and a plurality of p-type doped regions are formed in the n-well. For example, as shown in FIGS. 4A and 4B, n-type doped regions 122A and 122B can be formed within p-well 302A and p-type doped regions 123A and 123B can be formed within n-well 302B. To form n-type doped regions 122A and 122B and p-type doped regions 123A and 123B, hard mask layer 402 can be formed on p-well 302A and n-well 302B. As an example, and not as a limitation, as shown in FIGS. 4A and 4B, hard mask layer 402 can be patterned using photolithography to create openings in hard mask layer 402 for doping portions of p-well 302A while n-well 302B can be protected from doping by hard mask layer 402. N-type dopants can be added to p-well 302A through openings 404 in hard mask layer 402 using ion implantation or a diffusion process. N-type doped regions 122A and 122B can have n-type dopant concentration of about 1×10¹⁷ atoms/cm³ to about 1×10²² atoms/cm³. Similarly, to form p-type doped regions 123A and 123B, as shown in FIG. 4B, p-well 302A can be protected using hard mask layer 402 and hard mask layer on n-well 302B can be patterned using photolithography to create openings 404 in hard mask layer 402 for doping portions of n-well 302B. P-type dopants can be added to n-well 302B through openings 404 in hard mask layer 402 using ion implantation or a diffusion process. P-type doped regions 123A and 123B can have p-type dopant concentration of about 1×10¹⁷ atoms/cm³ to about 1×10²² atoms/cm³. After formation of n-type doped regions 122A and 122B and p-type doped regions 123A and 123B, hard mask layer 402 can be removed to form the structures shown in FIGS. 5A and 5B. A position of n-type doped regions 122A and 122B within p-well 302A and p-type doped regions 123A and 123B within n-well 302B, depends on a position of openings 404 in hard mask layer 402 with reference to (a) features already present on substrate 104 at this stage of fabrication, which are p-well 302A and n-well 302B, and (b) features on subsequent masking layers designed to align with n-type doped regions 122A and 122B and p-type doped regions 123A and 123B. In some embodiments, n-type doped regions 122A and 122B within p-well 302A and p-type doped regions 123A and 123B can be Referring to FIG. 2, in operation 215, a superlattice structure is formed on the substrate. For example, as shown in FIGS. 6A and 6B, superlattice structure 604 can be formed on p-well 302A and n-well 302B. Superlattice structure 604 is in contact with p-well 302A and n-well 302B formed in the upper portion of substrate 104. Superlattice structure 604 can be formed by depositing alternating layers of nanostructured layers 624 and nanostructured sacrificial layers 602. In some embodiments, nanostructured layers 624 can include Si without any substantial amount of Ge (e.g., with no Ge) and nanostructured sacrificial layers 602 can include SiGe. Nanostructured layers 624 are formed into NHC layers 124 in subsequent operations.

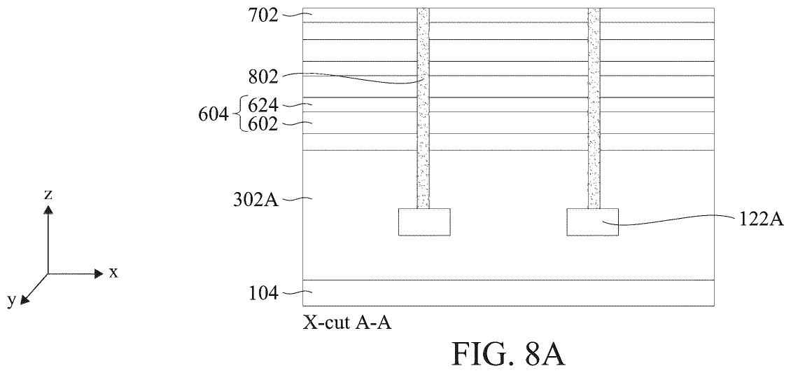

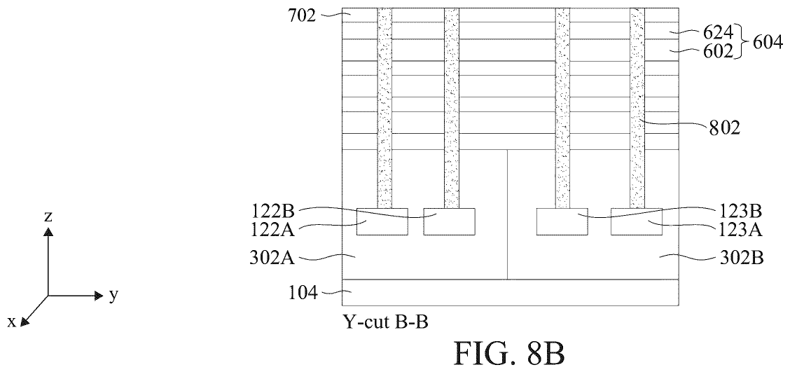

Referring to FIG. 2, in operation 220, a plurality of NVC regions are formed in the superlattice structure. For example, as described with reference to FIGS. 7A-8D, NVC regions 125 are formed within superlattice structure 604. The formation of NVC regions 125 can include sequential operations of (i) depositing a masking layer 702 (e.g. a photoresist layer or a hard mask layer) on the structures of FIGS. 6A and 6B, (ii) patterning openings 704 in masking layer 702, (iii) etching nanostructured layers 624, nanostructured sacrificial layers 602, and a portion of p-well 302A and n-well 302B through opening 704 to form openings 706 and expose top surfaces of n-type doped regions 122A-122B and p-type doped regions 123A-123B, as shown in FIGS. 7A-7C, (iv) depositing or epitaxially growing a nanostructured layer 802 within openings 706, as shown in FIGS. 8A and 8B, (v) removing patterned masking layer 702 from the structures of FIGS. 8A and 8B, and (vi) performing a chemical mechanical polishing (CMP) process on the structures of FIGS. 8A and 8B after removing patterned masking layer 702 to form NVC regions 125, as shown in FIGS. 9A and 9B. FIG. 9C shows a top view of NVC regions 125 and an uppermost nanostructured layer 624 of superlattice structure 604.

Patterning openings 704 in masking layer 702 includes patterning openings 704 in masking layer 702 aligned with n-type doped regions 122A-122B and p-type doped regions 123A-123B. For the NVC regions 125 to land on n-type doped regions 122A-122B and p-type doped regions 123A-123B, alignment of doped regions 122A-122B and 123A-123B and openings 704 is beneficial. Aligning openings 704 with n-type doped regions 122A-122B and p-type doped regions 123A-123B includes using photolithographic alignment of markers on a mask layout.

Etching nanostructured layers 624 and nanostructured sacrificial layers 602 can include alternatively etching with a first etching process to remove portions of nanostructured layers 624 through openings 704 and a second etching process to remove portions of nanostructured sacrificial layers 602 through openings 704. For example, for nanostructured layers 624 formed of Si and nanostructured sacrificial layers 602 formed of SiGe, the first etching process can have a higher etch selectivity towards Si than SiGe and can include a wet etching process with a mixture of ammonia hydroxide (NH₄OH) and hydrochloric acid HCl. The second etching process can have a higher etch selectivity towards SiGe than Si and can include a wet etching process with a mixture of sulfuric acid (H₂SO₄) and hydrogen peroxide (H₂O₂) and/or a mixture of NH₄OH, H₂O₂, and deionized (DI) water. A portion of p-well 302A and n-well 302B can be etched after the etching of nanostructured layers 624 and nanostructured sacrificial layers 602 to extend opening 706 into p-well 302A and n-well 302B to depth D1, as shown in FIGS. 7A and 7B. Etching p-well 302A and n-well 302B to depth D1 ensures that openings 706 reaches n-type doped regions 122A-122B and p-type doped regions 123A-123B.

The deposition or epitaxial growth of nanostructured layer 802 can include depositing or epitaxially growing a layer of Si, SiAs, SiP, SiC, SiCP, SiGe, SiGeB, GeB, SiGeSnB, a III-V semiconductor compound, or other suitable semiconductor materials. The CMP process can substantially coplanarize top surfaces of nanostructured layers 802 with uppermost nanostructured layers 624 to form structures shown in FIGS. 9A and 9B.

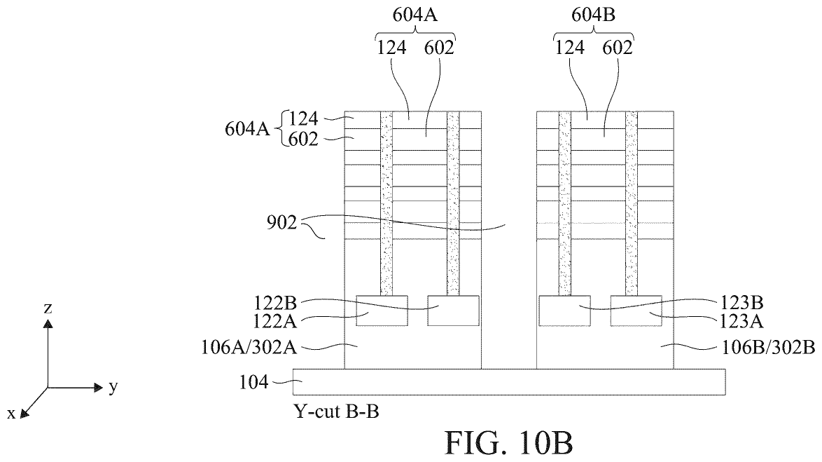

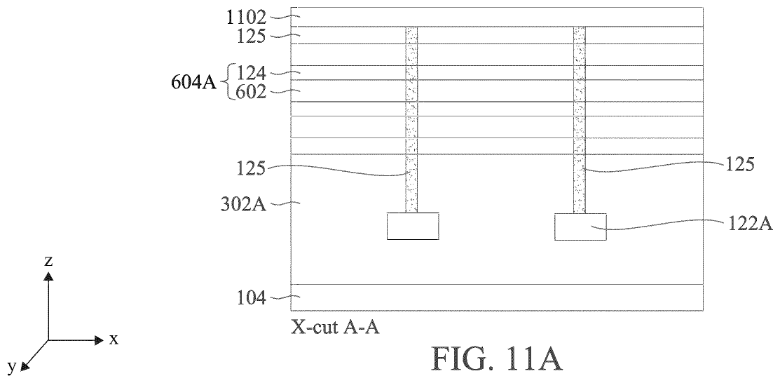

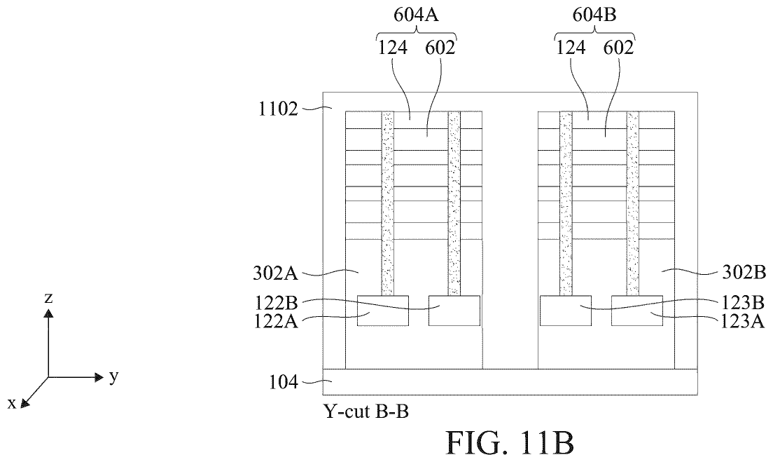

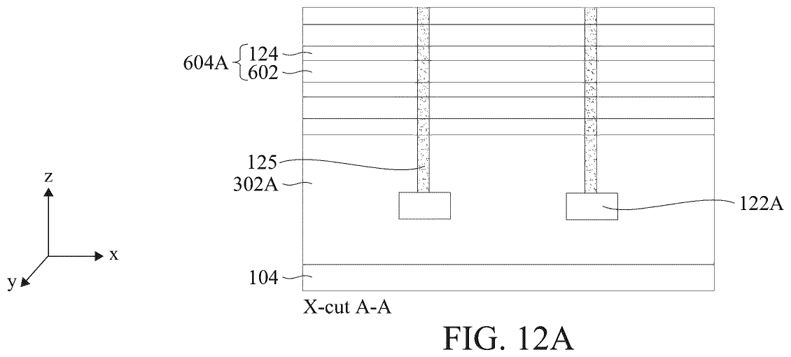

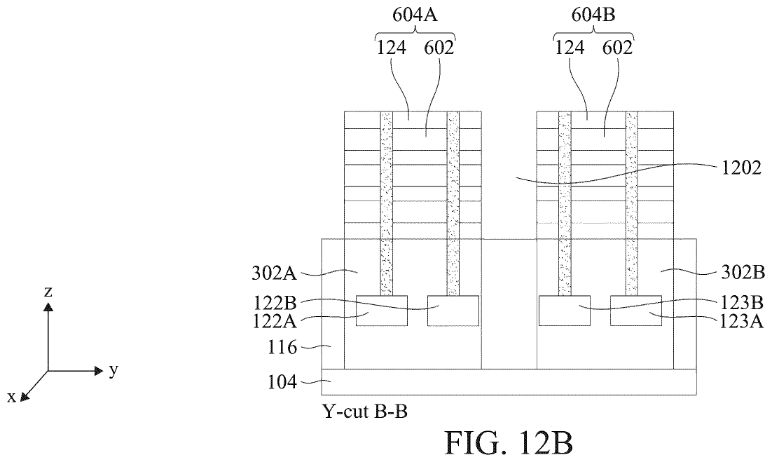

Referring to FIG. 2, in operation 225, first and second base structures and first and second superlattice structures are formed. For example, as shown in FIGS. 10A and 10B, first and second base structures 106A and 106B having p-well 302A and n-well 30B, respectively, are formed and first and second superlattice structures 604A and 604B are formed. Portions of substrate 104 having p-well 302A and n-well 302B and portions of superlattice structure 604 can be etched to form first and second base structures 106A and 106B and first and second superlattice structures 604A and 604B, as shown in FIGS. 10A and 10B. The etching of the portions of substrate 104 and superlattice structure 604 can form openings 902 between first and second base structures 106A and 106B and between first and second superlattice structures 604A and 604B, as shown in FIG. 10B. Second base structure 106B and second superlattice structure 604B are not visible in cross-sectional view of FIG. 10A. At the end of the etching process, (i) first base structure 106A having p-well 302A with n-type doped regions 122A-122B, and first superlattice structure 604A having NHC layers 124 and nanostructured sacrificial layers 602 can be formed, and (ii) second base structure 106B having n-well 302B with p-type doped regions 123A-123B, and second superlattice structure 604B having NHC layers 124 and nanostructured sacrificial layers 602 can be formed. Subsequent to the formation of openings 902, STI layer 1102 can be blanket deposited on the structure of FIGS. 10A and 10B to form structures shown in FIGS. 11A and 11B. STI layer 1102 can be recessed to form openings 1202 and STI regions 116 separating base structure 106A and 106B, as shown in FIGS. 12A and 12B. STI regions 116 are not visible in cross-sectional view of FIG. 11A.

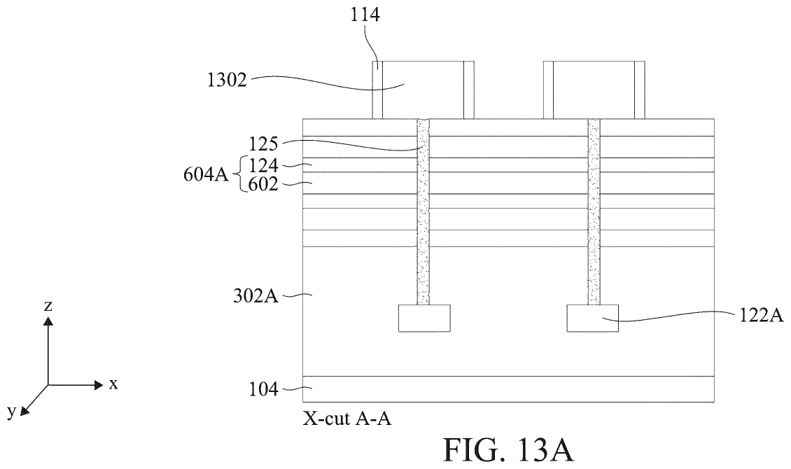

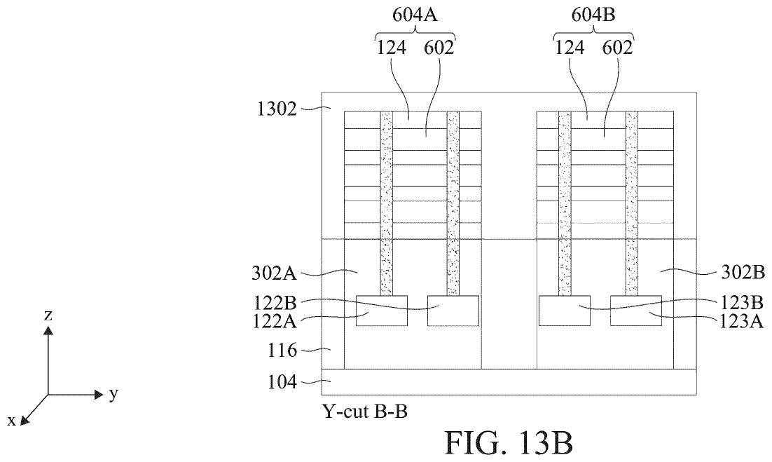

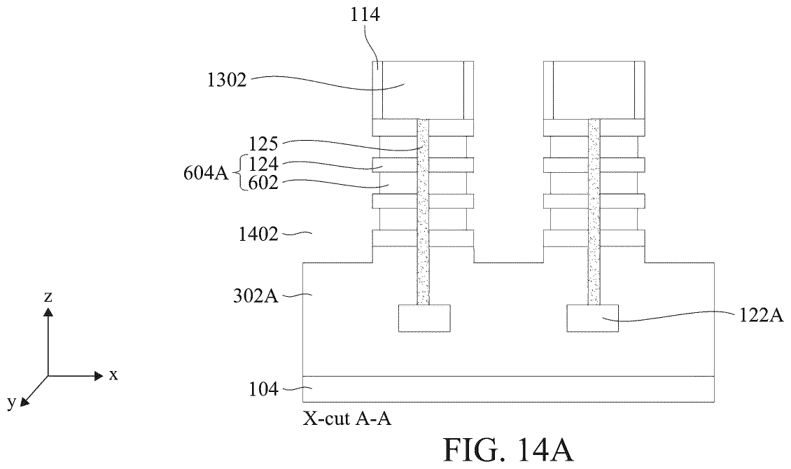

Referring to FIG. 2, in operation 230, polysilicon structures are formed on the first and second superlattice structures. For example, as shown in FIGS. 13A and 13B, polysilicon structure 1302 are epitaxially formed surrounding superlattice structures 604A and 604B and on STI regions 116. Outer gate spacers 114 can be formed on either side of polysilicon structures 1302.

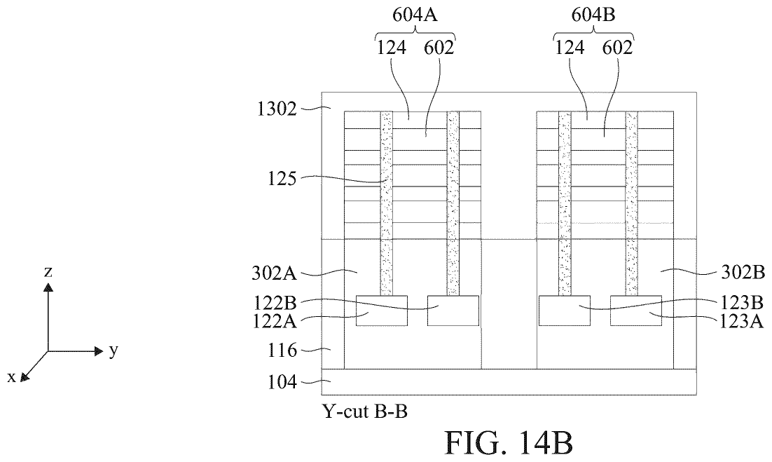

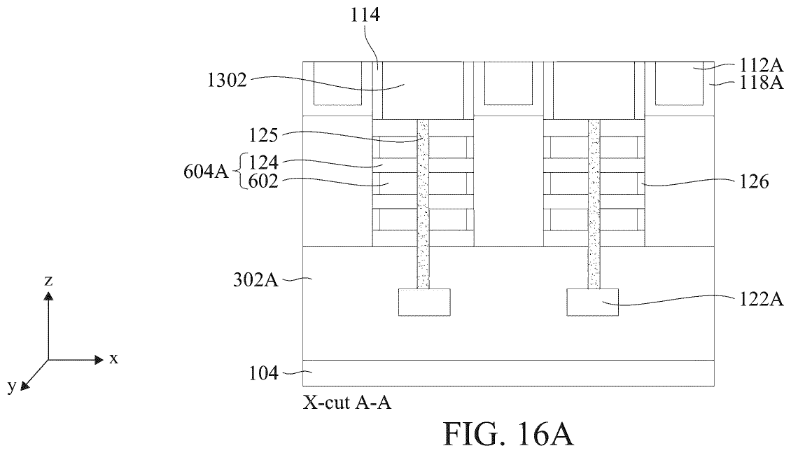

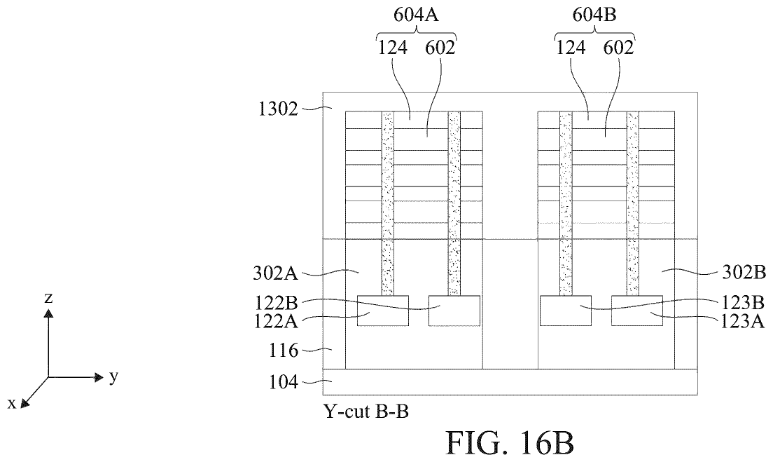

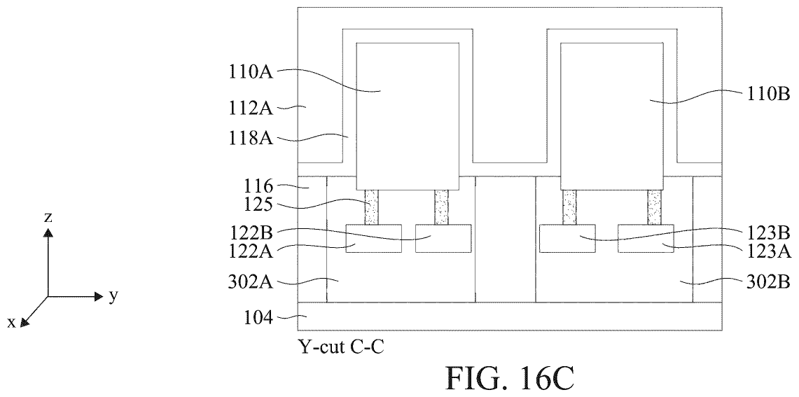

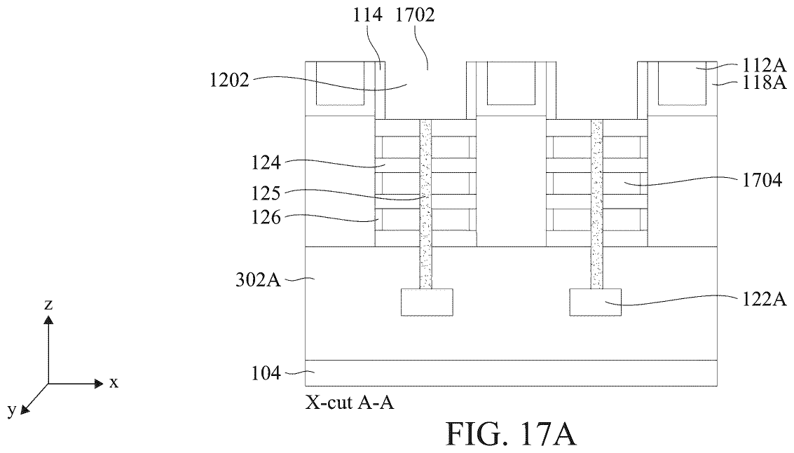

Referring to FIG. 2, in operation 235, source/drain (S/D) regions are formed on the first and second base structures. For example, as described with reference to FIGS. 14A-15C, S/D regions 110A and 110B are formed on base structures 106A and 106B respectively. The formation of S/D regions 110A and 110B can include sequential operations of (i) forming S/D openings 1402, through superlattice structures 604A and 604B, on portions of base structures 106A and 106B that are not underlying polysilicon structures 1302, as shown in FIG. 14A, and (ii) epitaxially growing n-type or p-type semiconductor materials within S/D openings 1402, as shown in FIGS. 15A and 15C. S/D regions 110A and 110B are not visible in cross-sectional view of FIG. 15B. After the formation of S/D regions 110A and 110B, first ESL 118A and first ILD layer 112A can be formed on S/D regions 110A and 110B to form the structure of FIGS. 16A and 16C.

In some embodiments, inner gate spacers 126 can be formed between operations (i) and (ii) of the formation process of epitaxial S/D regions 110A and 110B, as shown in FIG. 15A. The formation of inner gate spacers 126 can include sequential operations of (i) etching nanostructured sacrificial layers 602 along an X-axis to form the structure of FIG. 14A, (ii) depositing an insulating material on the structures of FIGS. 14A and 14B, and (iii), etching the deposited insulating material to form inners gate spacers 126, as shown in FIG. 15A. FIG. 14A shows etched nanostructured sacrificial layers 602 with linear sidewall profiles. However, in some embodiments, etched nanostructured sacrificial layers 602 can have curved sidewall profiles.

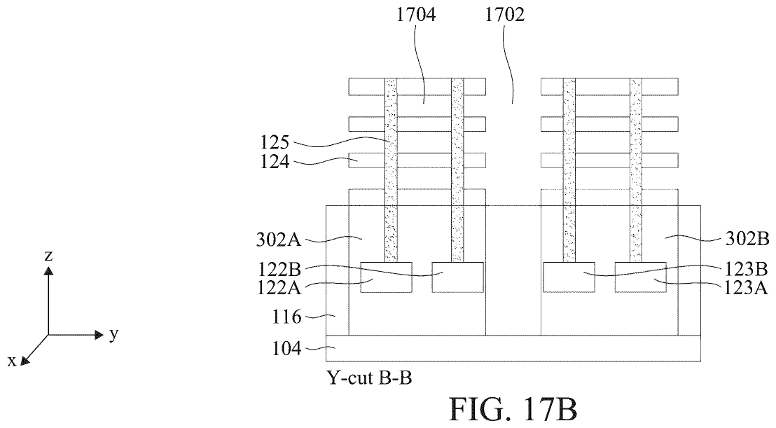

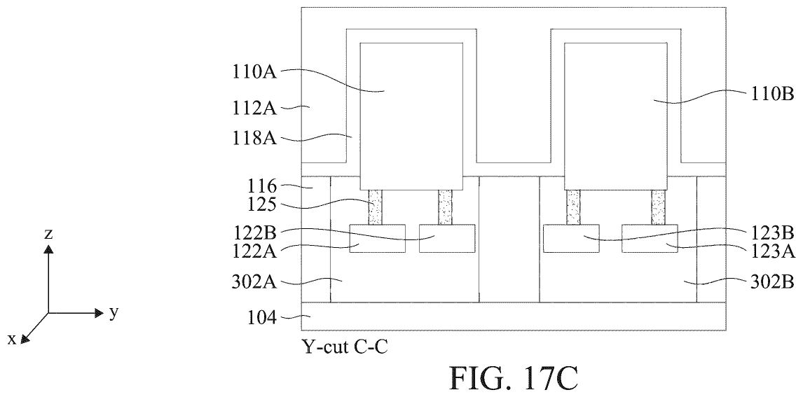

Referring to FIG. 2, in operation 240, first gate openings are formed on the first and second superlattice structures and second gate openings are formed within the first and second superlattice structures. For example, as shown in FIGS. 17A and 17B, first gate openings are formed on superlattice structures 604A and 604B. The formation of first gate openings can include etching polysilicon structures 1302 from the structures of FIGS. 16A and 16B to form the structures of FIGS. 17A and 17B. Second gate openings 1704 are formed within superlattice structures 604A and 604B. For example, as shown in FIGS. 17A and 17B, second gate openings 1704 are formed within superlattice structures 604A and 604B. The formation of second gate openings 1704 can include etching nanostructured sacrificial layers 602 from the structures of FIGS. 16A and 16B to form the structures of FIGS. 17A and 17B. The etching of nanostructured sacrificial layers 602 can include a wet etching process with a mixture of H₂SO₄ and hydrogen peroxide H2O2 and/or a mixture of NH₄OH, H₂O₂, and DI water. Gate openings and 1704 are not visible in cross-sectional view of FIG. 17C.

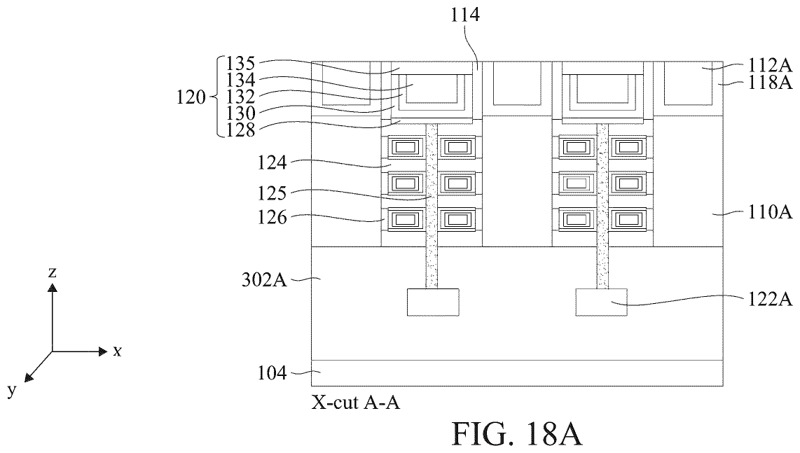

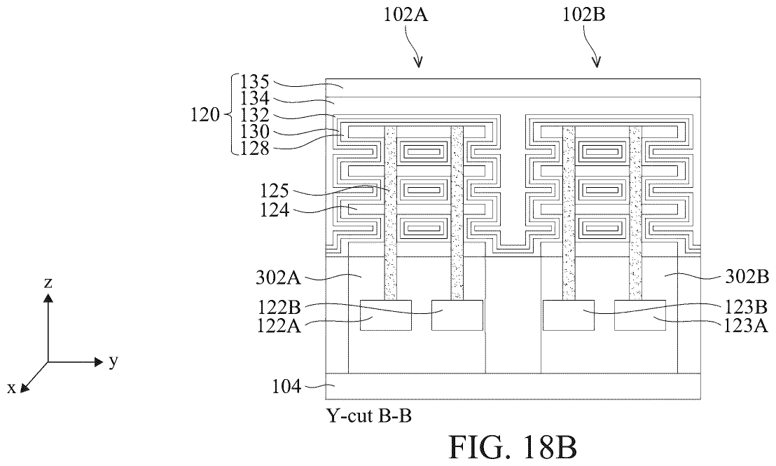

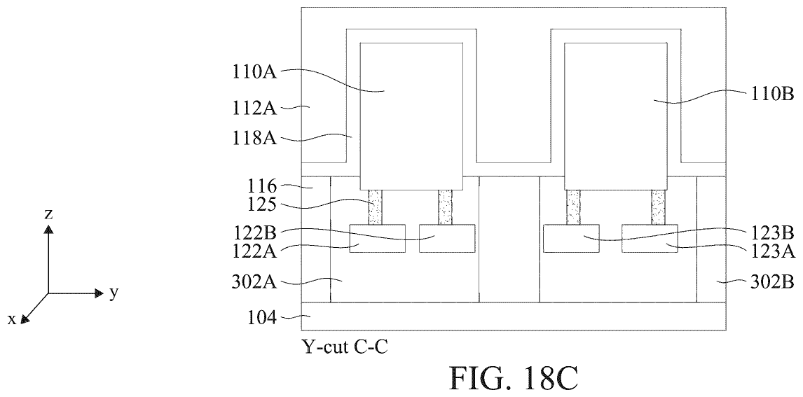

Referring to FIG. 2, in operation 245, gate structures are formed in the first and second gate openings. For example, as described with reference to FIGS. 18A and 18B, gate structures 120 are formed in first gate openings 1702 and second gate openings 1704. As shown in FIGS. 18A and 18B, the formation of gate structure 120 can include sequential operations of (i) forming IL layer 128 on the exposed regions of NHC layers 124, NVC region 125, and STI regions 116, as shown in FIGS. 18A and 18B, (ii) depositing HK gate dielectric layer 130 on IL layer 128, as shown in FIGS. 18A and 18B, (iv) depositing WFM layer 132 on HK gate dielectric layer 130, as shown in FIGS. 18A and 18B, (vi) depositing gate metal fill layer 134 on WFM layer 132 to fill gate openings 1602 and 1604, as shown in FIGS. 18A and 18B, and (vii) forming gate capping layer 135, as shown in FIGS. 18A and 18B. Gate structures 120 are not visible in cross-sectional view of FIG. 18C.

In some embodiments, IL layer 128 can be formed by exposing the structures of FIGS. 17A and 17B to an oxidizing ambient. The oxidizing ambient can include a combination of ozone (O₃), a mixture of ammonia hydroxide, hydrogen peroxide, and water, and/or a mixture of hydrochloric acid, hydrogen peroxide, and water. The deposition of HK gate dielectric layer 130 can include depositing a HK gate dielectric material with a thickness of about 1 nm to about 2 nm in an atomic layer deposition (ALD) process using hafnium chloride (HfCl4) as a precursor at a temperature of about 250° C. to about 350° C.

In some embodiments, WFM layer 132 can be an n-type WFM layer formed by depositing about 1 nm to about 3 nm thick Al-based metallic layer with an ALD or a chemical vapor deposition (CVD) process using a mixture of titanium tetrachloride (TiCl₄) and titanium ethylene aluminum (TEAl) or a mixture of tantalum chloride (TaCl₅) and trimethylaluminium (TMA) as precursors at a temperature ranging from about 350° C. to about 450° C. In some embodiments, the Al-based metallic layer can be deposited in an ALD process of about 4 cycles to about 12 cycles, where one cycle can include sequential periods of: (i) first precursor gas (e.g., TiCl₄ or TaCl₅) flow, (ii) a first gas purging process, (iii) a second precursor gas (e.g., TEAl or TMA) gas flow, and (iv) a second gas purging process.

In some embodiments, WFM layer 132 can be a p-type WFM layer formed by depositing Al-free metallic layer can include depositing about 1 nm to about 3 nm thick Al-free metallic layer with an ALD or a CVD process using TiCl₄ or a mixture of WCl₅ and NH₃ as precursors at a temperature ranging from about 400° C. to about 450° C. In some embodiments, Al-free metallic layer can be deposited in an ALD process of about 40 cycles to about 100 cycles, where one cycle can include sequential periods of: (i) first precursor gas (e.g., TiCl4 or WCl5) flow, (ii) a first gas purging process, (iii) a second precursor gas (e.g., NH3) gas flow, and (iv) a second gas purging process.

In some embodiments, the deposition of gate metal fill layer 134 can include depositing a fluorine-free metal layer with an ALD process using WCl₅ or a mixture of WCl₆ and H₂ as precursors at a temperature ranging from about 400° C. to about 500° C. In some embodiments, the fluorine-free metal layer can be deposited in an ALD process of about 160 cycles to about 320 cycles, where one cycle can include sequential periods of: (i) first precursor gas (e.g., WCl₅ or WCl₆) flow, (ii) a first gas purging process, (iii) a second precursor gas (e.g., H₂) gas flow, and (iv) a second gas purging process. A CMP process after the deposition of gate metal fill layer 134 can substantially coplanarize top surfaces of HK gate dielectric layer 130, WFM layer 132, and gate metal fill layer 134 with top surface of first ILD layer 112A.

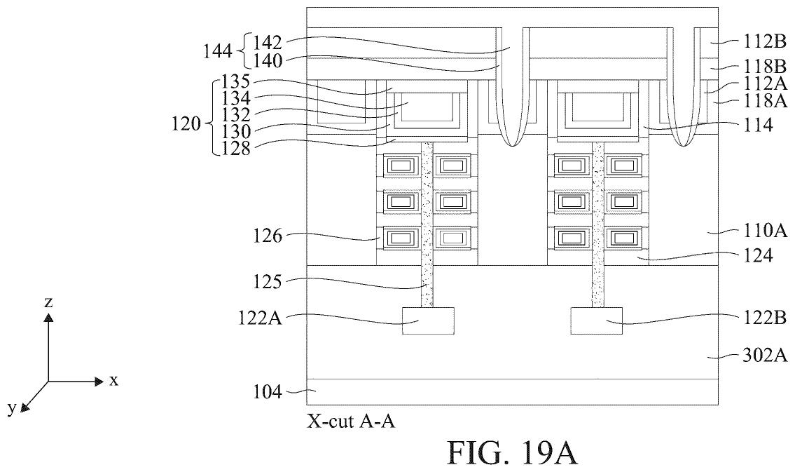

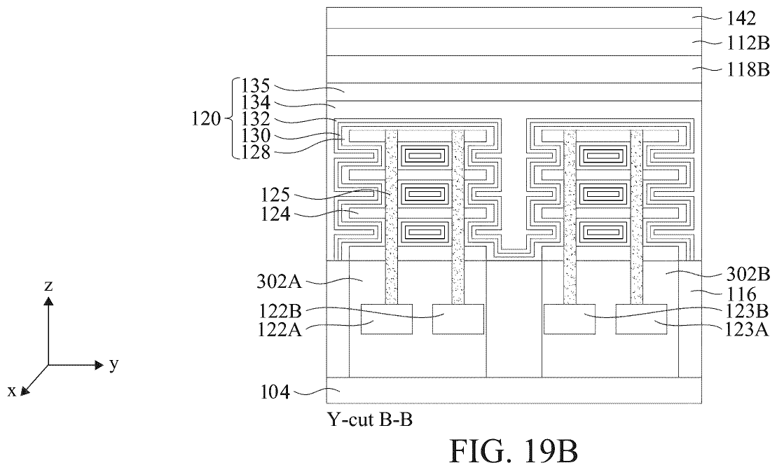

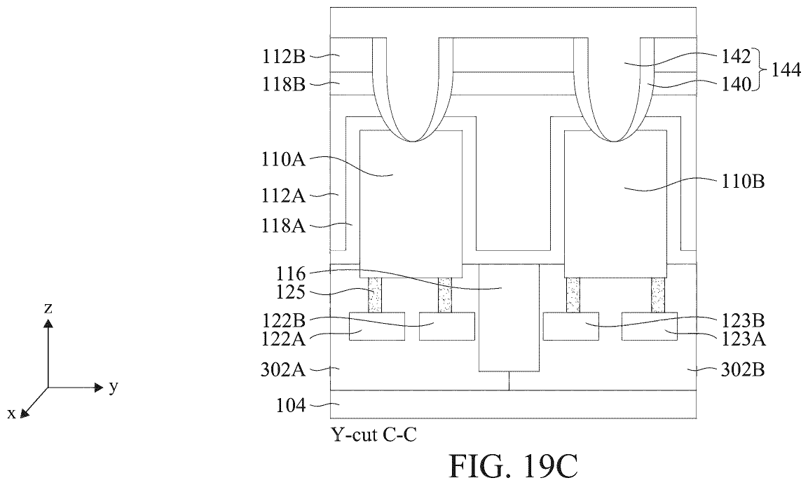

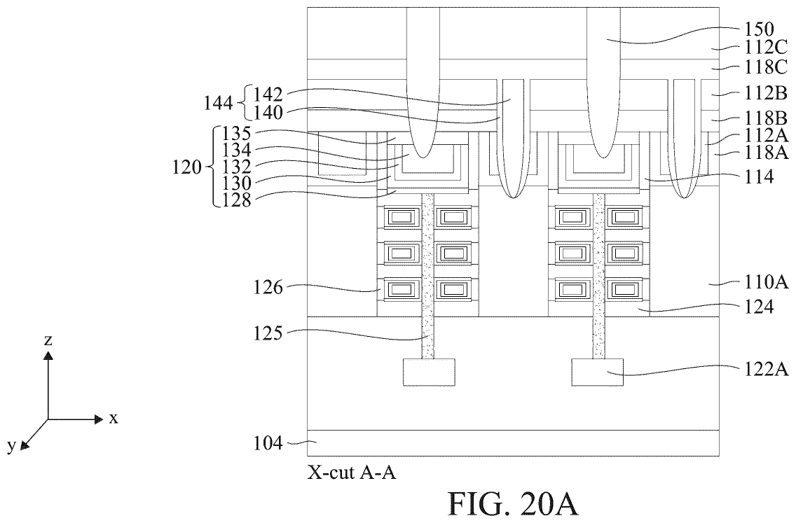

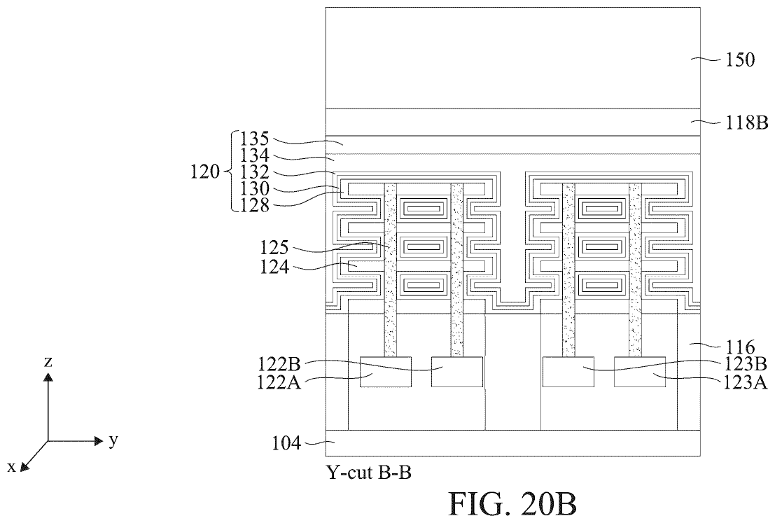

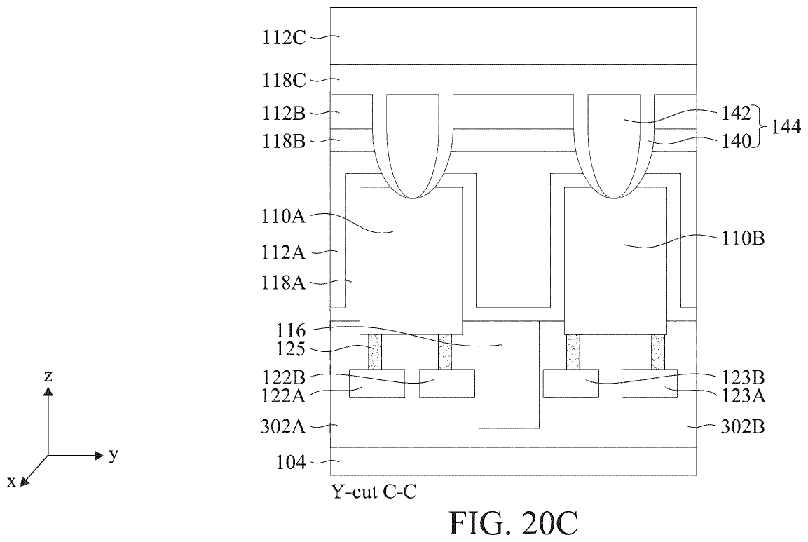

Referring to FIG. 2, in operation 250, contact structures are formed on the S/D regions and gate structures. For example, as described with reference to FIGS. 19A-20C, S/D contact structures 144 are formed on epitaxial S/D regions 110A and 110B and gate contact structures 150 are formed on gate structure 120. The formation of S/D contact structures 144 can include sequential operations of (i) depositing second ESL 118B on structure of FIGS. 18A-18C, (ii) depositing second ILD layer 112B on second ESL 118B, (iii) forming S/D contact openings (not shown) within first and second ILD layers 112A and 112B and first and second ESL 118A and 118B, (iv) forming silicide layers (not shown) within the S/D contact openings, (v) depositing liners 140 in the S/D contact openings, as shown in FIGS. 19A-19C (vi) depositing S/D contact metal layer 142 on silicide layers and liners 140 to fill the S/D contact openings, as shown in FIGS. 19A-19C, and (vii) performing a CMP process on the deposited S/D contact metal layer 142 to substantially coplanarize top surfaces of S/D contact metal layer 142 and liners 140 with top surface of second ILD layer 112B, as shown in FIGS. 20A and 20C.

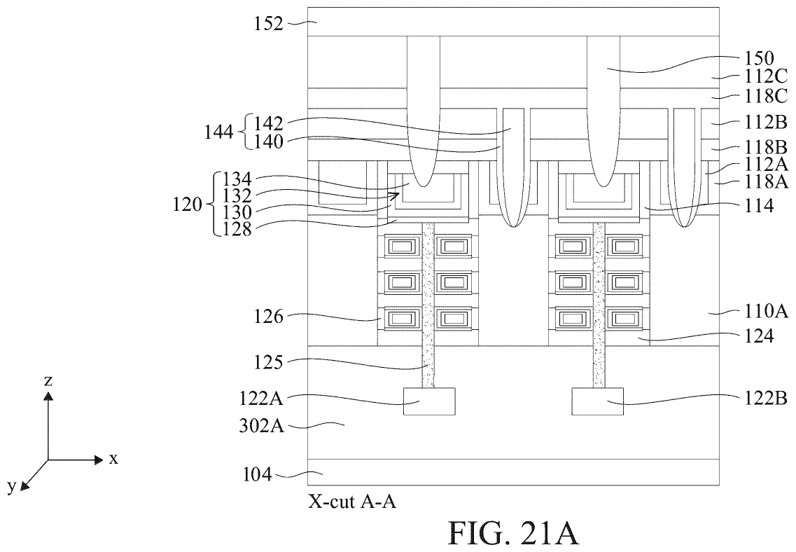

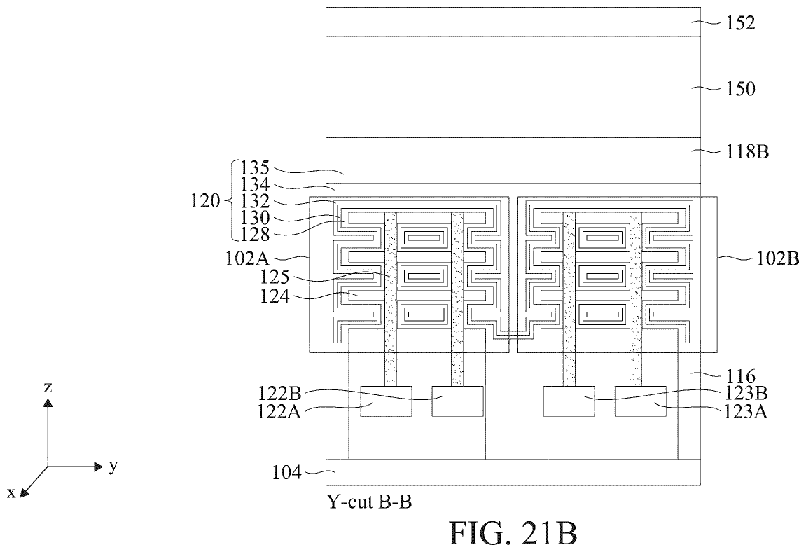

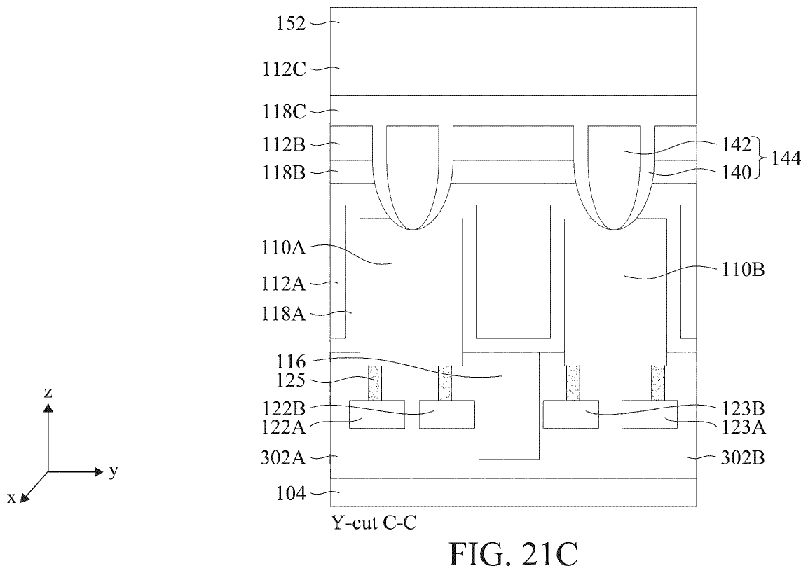

The formation of gate contact structures 150 can include sequential operations of (i) depositing third ESL 118C on second ILD layer 112B, (ii) depositing third ILD layer 112C on third ESL 118C, (iii) forming gate contact openings (not shown) within second and third ILD layers 112B and 112C and second and third ESLs 118B and 118C, (iv) depositing gate contact metal layer 150 within gate contact openings, and (v) performing a CMP process on the deposited gate contact metal layer 150 to substantially coplanarize top surfaces of gate contact metal layer 150 with a top surface of third ILD layer 112C, as shown in FIG. 20A. Subsequent to S/D contact and gate contact formation, interconnect structure 152 can be formed on third ILD layer 112C as shown in FIGS. 21A-21C.

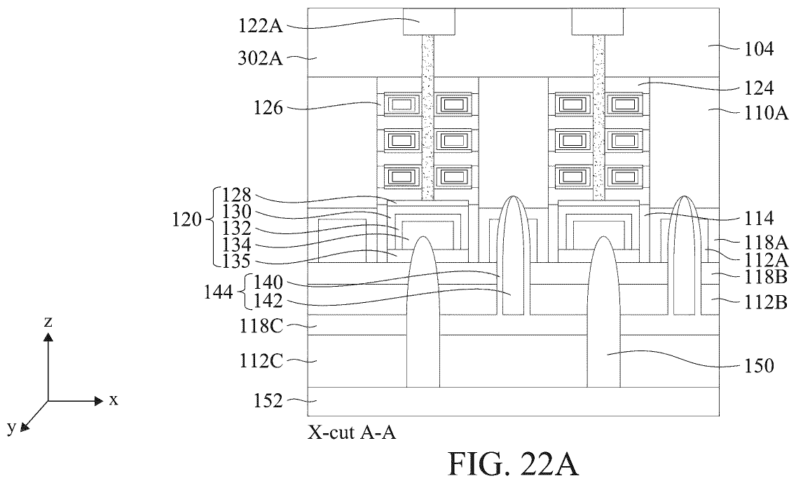

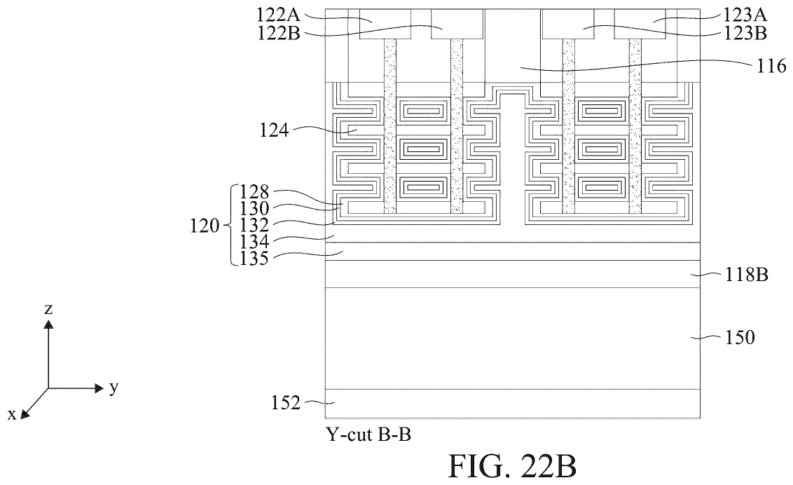

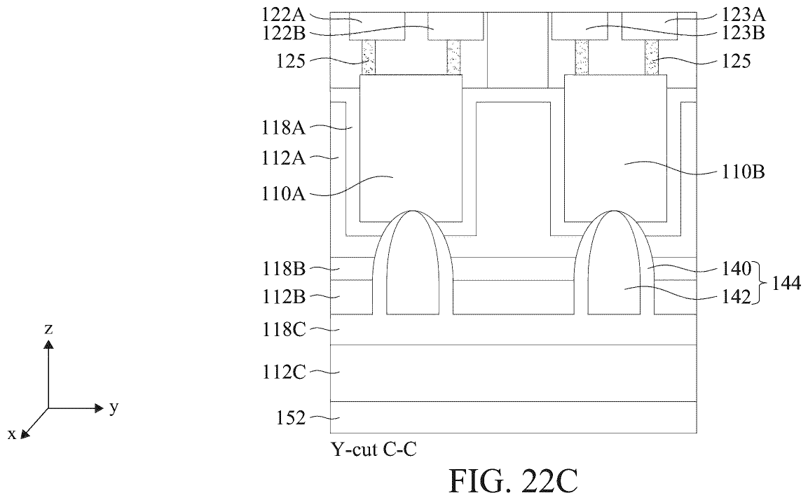

Referring to FIG. 2, in operation 255, the substrate is flipped and a portion of the backside of the substrate is removed. In some embodiments, to prevent damaging structures formed on the front side of substrate 104, the front side of substrate 104 can be protected using a masking layer (not shown) prior to flipping the substrate. As shown in FIGS. 22A-22C, after flipping substrate 104, a CMP process can be performed on to remove a portion of substrate 104 to expose backsides of n-type doped regions 122A-122B and p-type doped regions 123A-123B. The CMP process can include polishing STI regions 116, substrate 104, p-well 302A, and n-well 302B. The chemical mechanical polishing process can be a timed processed. Through prior experimentation, an optimized time duration for removing STI region 116, substrate 104, p-well 302A, and n-well 302B to expose n-type doped regions 122A and 122B and p-type doped regions 123A and 123B can be obtained.

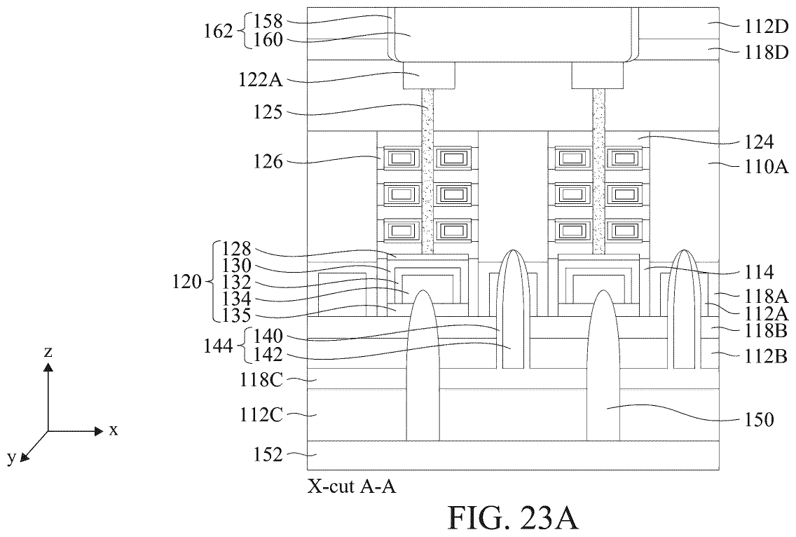

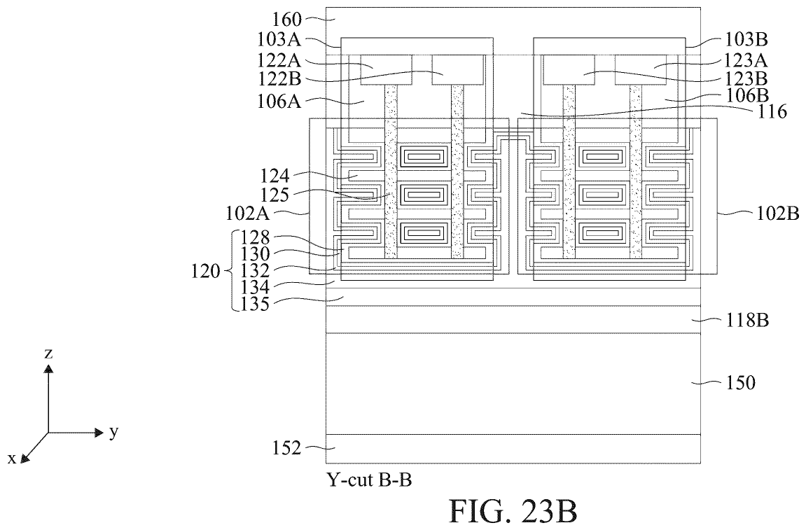

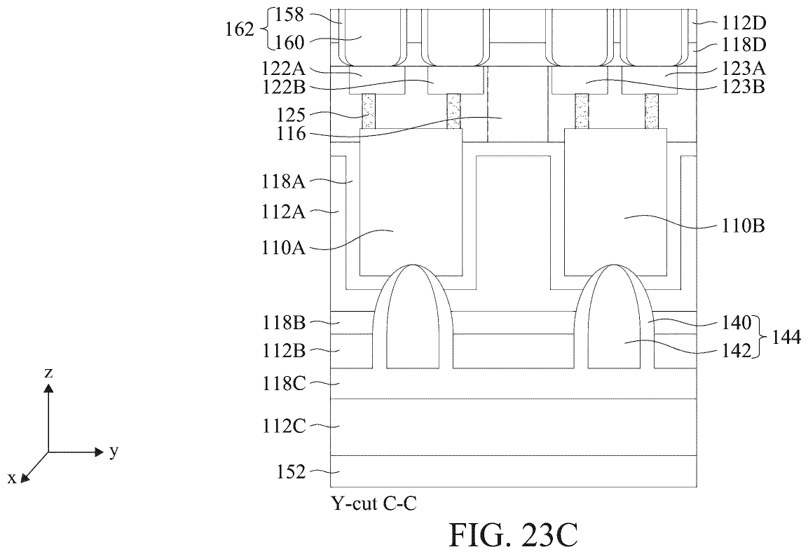

Referring to FIG. 2, in operation 260, backside contact structures are formed on the backside of the substrate. For example, as shown in FIGS. 23A-23C, backside contact structures 162 are formed on n-type doped regions 122A-122B and p-type doped regions 123A-123B. The formation of backside contact structures 162 can include sequential operations of (i) depositing backside ESL 118D on structure of FIGS. 22A-22C, (ii) depositing backside ILD layer 112D on backside ESL 118D, (iii) forming backside contact openings (not shown) within backside ILD layer 112D and backside ESL 118D, (iv) forming backside silicide layers (not shown) within the backside contact openings, (v) depositing backside liners 158 in the backside contact openings, (vi) depositing backside contact metal layer 160 on backside silicide layers and backside liners 158 to fill the backside contact openings, and (vii) performing a CMP process on the deposited backside contact metal layer 160 to substantially coplanarize top surfaces of backside contact metal layer 160 and backside liners 158 with top surface of backside ILD layer 112D.

The present disclosure provides backside devices 103A and 103B formed within a substrate 104 and powered through the backside of the substrate 104. The backside devices 103A and 103B can be fabricated as a FET which can be a backside nFET 103A or a backside pFET 103B. The front side of the substrate can have front side devices 102A and 102B (e.g., n-type FETs, p-type FETs, gate-all-around p-type GAA FETS and n-type GAA FETs). To form the backside devices 103A and 103B, doped regions 122A-122B and 123A-123B can be formed within substrate 104. Doped regions 122A-122B can function as source/drain regions of backside devices 103A and doped regions 123A and 123B can function as source/drain regions of backside devices 103B. The source/drain regions can be powered or controlled through electrical contacts on the backside of the substrate. In some embodiments, a common gate structure 120 can control the front side semiconductor devices 102A and 102B and the backside devices 103A and 103B. For example, FETs 102A and 102B or GAA FETs 102A and 102B can be formed on a front side of the substrate. Doped regions 122A-122B and 123A-123B which can function as source/drain regions for a backside device can be formed within the substrate. The source/drain regions 122A-122B and 123A-123B for a backside device can be controlled through backside contact structures 162 on the backside of the substrate. To share a common gate 120, the FET 102A and 102B on the front side of the substrate, includes NVC regions 125 disposed within a plurality of NHC layers 124 disposed on base structures 106A and 106B. The NVC regions 125 are connected to the source and drain 122A-122B and 123A-123B of the backside devices 103A and 103B respectively. Gate structure 120 of the front side GAA FET 102A and 102B wraps around NVC regions 125. Vertical portions of two adjacent NVC regions 125 connected by a NHC layer 124 of the plurality of NHC layers form a channel for the backside device, which can be controlled by gate structure 120.

In some embodiments, a semiconductor device includes a base structure having a first doped region, a plurality of nanostructured channel layers disposed on the first doped region, a second doped region disposed in the first doped region, a vertical channel region disposed in the plurality of nanostructured channel layers and in contact with the second doped region, and a gate structure surrounding the plurality of nanostructured channel layers and second vertical channel region.

In some embodiments, a semiconductor device includes a base structure disposed on a substrate, a doped region disposed in the base structure, a horizontal nanostructured layer disposed on the base structure, a vertical nanostructured region surrounded by the horizontal nanostructured layer, a source/drain region adjacent to the horizontal nanostructured layer, and a gate structure surrounding the horizontal nanostructured layer and the vertical nanostructured region.

In some embodiments, a method includes forming a first doped region in a substrate, forming a second doped region in the first doped region, forming a superlattice structure with nanostructured layers and sacrificial nanostructured layers on the first doped region, forming a vertical nanostructured channel region in the superlattice structure, forming a polysilicon structure on the superlattice structure and the vertical nanostructured channel region, and replacing the polysilicon structure and the sacrificial nanostructured layers with a gate structure surrounding the nanostructured layers and the vertical nanostructured channel region.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a base structure comprising a first doped region;
a plurality of nanostructured channel layers disposed on the first doped region;
a second doped region disposed in the first doped region;
a vertical channel region disposed in the plurality of nanostructured channel layers and in contact with the second doped region; and
a gate structure surrounding the plurality of nanostructured channel layers and second vertical channel region.

2. The semiconductor device of claim 1, wherein the plurality of nanostructured channel layers extend in a first direction and the vertical channel region extends in a second direction perpendicular to the first direction.

3. The semiconductor device of claim 1, wherein the gate structure surrounds the plurality of nanostructured channel layers about a first axis and surrounds the vertical channel region about a second axis perpendicular to the first axis.

4. The semiconductor device of claim 1, wherein the vertical channel region is in contact with a top surface of the second doped region.

5. The semiconductor device of claim 1, wherein a first portion of the vertical channel region is surrounded the gate structure and a second portion of the vertical channel region is surrounded by the first doped region.

6. The semiconductor device of claim 1, wherein a material of the vertical channel region is different from a material of the plurality of nanostructured channel layers.

7. The semiconductor device of claim 1, wherein the vertical channel region comprises a doped semiconductor region.

8. The semiconductor device of claim 1, wherein the vertical channel region comprises a circular cross-section profile along a first plane and a rectangular cross-sectional profile along a second plane perpendicular to the first plane.

9. The semiconductor device of claim 1, wherein the first doped region comprises first dopants of a first conductivity type, and
wherein the second doped region comprises second dopants of a second conductivity type.

10. The semiconductor device of claim 1, further comprising a backside contact structure disposed on a backside of the second doped region.

11. A semiconductor device, comprising:
a base structure disposed on a substrate;
a doped region disposed in the base structure;
a horizontal nanostructured layer disposed on the base structure;
a vertical nanostructured region surrounded by the horizontal nanostructured layer;
a source/drain region adjacent to the horizontal nanostructured layer; and
a gate structure surrounding the horizontal nanostructured layer and the vertical nanostructured region.

12. The semiconductor device of claim 11, wherein the base structure comprises p-type dopants and the doped region comprises n-type dopants.

13. The semiconductor device of claim 11, wherein the vertical nanostructured region is in contact with a front side of the doped region.

14. The semiconductor device of claim 11, wherein a first portion of the vertical nanostructured region is surrounded the gate structure and a second portion of the vertical nanostructured region is surrounded by the horizontal nanostructured layer.

15. The semiconductor device of claim 11, further comprising a backside side contact structure in contact with a backside of the doped region.

16. The semiconductor device of claim 11, wherein a top surface of the vertical nanostructured region is substantially coplanar with a top surface of the horizontal nanostructured layer.

17. A method, comprising:
forming a first doped region in a substrate;
forming a second doped region in the first doped region;
forming a superlattice structure with nanostructured layers and sacrificial nanostructured layers on the first doped region;
forming a vertical nanostructured channel region in the superlattice structure;
forming a polysilicon structure on the superlattice structure and the vertical nanostructured channel region; and
replacing the polysilicon structure and the sacrificial nanostructured layers with a gate structure surrounding the nanostructured layers and the vertical nanostructured channel region.

18. The method of claim 17, wherein forming the vertical nanostructured channel region comprises etching the superlattice structure to form an opening extending into the first doped region.

19. The method of claim 17, wherein forming the vertical nanostructured channel region comprises etching the superlattice structure and the first doped region to expose a top surface of the second doped region.

20. The method of claim 17, wherein forming the vertical nanostructured channel region comprises epitaxially growing a semiconductor layer in the superlattice structure and the first doped region.
